(19) United States
(12) Patent Application Publication
(10) Pub. No.: US 2026/0311322 A1
(43) Pub. Date: Oct. 8, 2026

(54) COMPUTERIZED METROLOGY FOR MEASURING SHAPED OBJECTS

(71) Applicant: CINDERGLOW TECHNOLOGIES LLC, Oceanside, CA (US)

(72) Inventor: Kevin Richard KAUFMANN, Oceanside, CA (US)

(21) Appl. No.: 19/639,991

(22) Filed: Apr. 6, 2026

Related U.S. Application Data
(60) Provisional application No. 63/785,339, filed on Apr. 8, 2025.
(60) Provisional application No. 63/838,313, filed on Jul. 3, 2025.
(60) Provisional application No. 63/948,946, filed on Dec. 26, 2025.
(60) Provisional application No. 64/004,770, filed on Mar. 13, 2026.

(51) Int. Cl. G06T 7/00; G06F 30/20

(52) U.S. Cl. CPC G06T 7/001; G06F 30/20

(57) ABSTRACT

An object is measured with data from different sources. The data are combined to compare the object with a reference object. The data may comprise profilometry data, color data, and reflectance data. A plurality of types of data such as color data and reflectance data can be associated with each point of a plurality of points of profile data. A digital twin may be created from the data. The data from the digital twin may be compared to a reference digital twin. The digital twin of the object being evaluated comprises similar data to the reference digital twin, such as a reference standard of the object. The reference data may also have a plurality of types of data such as profile data, color data and reflectance data associated with each point of a plurality of points on a reference object such as a reference digital twin.

### RELATED APPLICATIONS

This application claims the benefit under 35 U.S.C. § 119 (e) of U.S. Provisional Patent Applications No. 63/785,339, filed Apr. 8, 2025; U.S. Patent Application No. 63/838,313, filed Jul. 3, 2025; U.S. Patent Application No. 63/948,946, filed Dec. 26, 2025; and Patent Application No. 64/004,770, filed Mar. 13, 2026, which are incorporated, in their entirety, by this reference.

### BACKGROUND

The prior approaches to measuring and evaluating objects such as fabricated or stamped parts can be less than ideal in at least some instance. For example, the fabricated object may have subtle details or defects that are not readily evaluated with prior approaches. For example, some visible defects can be submicron and difficult to detect with automated approaches like machine vision. For example, some objects may have complex surfaces with patterned rims and surface relief that can vary from object to object. In some instances, different types of data can be present from different sources such as different measurement and imaging devices, which can further complicate automation. Although humans can perform evaluation tasks such as quality control, human results can be somewhat variable and less objective than would be ideal.

One such example of the evaluation of fabricated objects is coin grading. Manual coin grading by humans is laborious, inaccurate, and inconsistent in at least some instances. Manual coin grading may include having a person view a coin and grade the coin based at least in part on visual inspection, which can result in somewhat inconsistent results in at least some instances.

With some collectibles such as coins, the coins may not be perfectly minted, which can be related to several factors such as wear on the dies, polishing of the dies, foreign substances, or less than ideal pressure or distance between the dies, for example. Although it can be helpful to evaluate the strike designation of a minted coin, the prior approaches can be somewhat subjective and less quantitative than would be ideal.

Work in relation to the present disclosure suggests that the prior approaches to evaluating coins can be somewhat more subjective than would be ideal. Manual coin grading can be labor intensive and will typically involve a person looking at several areas of a coin to grade the coin, such as the obverse (front), obverse (back), and the edge. However, with human grading the evaluation of these areas of the coin can be somewhat subjective. The condition of some of these areas may be related to wear, handling, storage and manufacturing, for example. Coin grading can involve looking at different areas of the coins, such as the fields and devices, and may involve looking at the entire coin. With some coins, the fields are relatively flat and open areas of the coin, which can be used to spot imperfections related to luster, for example. When coins are minted, they can be ejected into large canvas bags where they clank against one another, which can create bag marks, nicks, and scratches in at least some instances. The high points on a coin can be prone to wear, and the prior approaches may less than ideally evaluate this type of wear.

Work in relation to the present disclosure also suggests that prior approaches to coin grading can be somewhat black box and subjective in nature, and it would be helpful to provide quantitative data related to the grading process.

With human coin grading, the number of locations measured can be less than ideal, and the reporting of the data that led to a particular grade can be less than ideal.

In light of the above, it would be desirable to have improved approaches to grading collectible such as coins that ameliorate at least some of the limitations of the prior approaches.

### SUMMARY

The presently disclosed systems and methods provide improved measurement of fabricated objects. In some embodiments data from different sources are combined to compare an object with a reference object. The data from different sources may comprise profilometry data, color data, and reflectance data for example. In some embodiments, a digital twin is created from the data. The data from the digital twin may be compared to a reference digital twin. In some embodiments, the digital twin of the object being evaluated comprises similar data to the reference digital twin, such as a gold standard of the part. In some embodiments, a plurality of types of data such as color data and reflectance data are associated with each point of a plurality of points of the profile data of the object being evaluated such as a digital twin. In some embodiments, the reference data has a plurality of types of data such as color data and reflectance data associated with each point of a plurality of points of the profile data such as a reference digital twin.

In a first aspect, a method of comparing an object with a reference comprises:
receiving data acquired from the object, the data comprising topography data;
generating a digital twin of the object from the topography data; and
comparing the topography data of the digital twin with a reference comprising topography data.

### INCORPORATION BY REFERENCE

All patents, applications, and publications referred to and identified herein are hereby incorporated by reference in their entirety, and shall be considered fully incorporated by reference even though referred to elsewhere in the application.

### BRIEF DESCRIPTION OF THE DRAWINGS

A better understanding of the features, advantages and principles of the present disclosure will be obtained by reference to the following detailed description that sets forth illustrative embodiments, and the accompanying drawings of which:

FIG. 1 shows a diagram of a computerized system, in accordance with some embodiments;

FIG. 2 shows a perspective view of an image acquisition device, in accordance with some embodiments;

FIG. 3 shows a view of a grade report from the computerized systems, in accordance with some embodiments;

FIG. 4 shows a view of a collectible and a view of strike designation scores of the grade report from the computerized systems, in accordance with some embodiments;

FIG. 5 shows a view of a collectible and a view of the detail and wear scores of the grade report from the computerized systems, in accordance with some embodiments;

FIG. 6 shows views of a collectible and a view of the roughness scores of the grade report from the computerized systems, in accordance with some embodiments;

FIG. 7 shows views of a collectible and a view of the edge analysis grading scores and details of the grade report from the computerized systems, in accordance with some embodiments;

FIG. 8 shows a digital twin of a numismatic collectible, in accordance with some embodiments;

FIG. 9 shows views of several collectibles where the computerized systems have detected various forms of damage and/or reasons for assigning “No Grade” to the collectible, in accordance with some embodiments;

FIGS. 10A and 10B show views and the luster grading scores of a grade report of a first collectible and a second collectible, respectively, generated with a computerized systems, in accordance with some embodiments;

FIG. 11 shows a view of a collectible and a view of the strike and method of manufacture analysis from the computerized system, in accordance with some embodiments;

FIG. 12 shows a user interface configured to allow a user to interact with the data of the numismatic collectible, in accordance with some embodiments;

FIG. 13 shows a view of a collectible, and a view of the cameo grading scores of the grade report from the computerized systems, in accordance with some embodiments;

FIG. 14 shows a view of the obverse and reverse of a collectible, and a view of the toning grading scores of the grade report from the computerized system, in accordance with some embodiments;

FIG. 15 shows a view of a collectible, a view of the marks analysis routine, and a view of the marks grading scores from the computerized systems, in accordance with some embodiments;

FIG. 16 shows physical characteristics of a collectible that can be used to uniquely identify the collectible, in accordance with some embodiments;

FIG. 17 shows a collectible being evaluated through an enclosure (e.g., coin capsule or slab), in accordance with some embodiments;

FIG. 18 schematically illustrates a computerized system for grading collectibles, in accordance with some embodiments;

FIG. 19 shows a flowchart of a method of grading a collectible, in accordance with some embodiments;

FIG. 20 shows a diagram illustrating an example of a loading tray for grading one or more coins, in accordance with some embodiments;

FIG. 21 shows a mobile and/or remote grading system, in accordance with some embodiments;

FIG. 22 shows a diagram illustrating an example of a protective slab, in accordance with some embodiments;

FIG. 23 shows a view of the obverse a collectible, and a view of the copper color scores of the grade report from the computerized systems, in accordance with some embodiments;

FIG. 24 shows a view of the obverse a collectible, and a view of the surface and bulk chemistry report of the grade report from the computerized systems, in accordance with some embodiments;

FIG. 25 shows a view of a golden image and its relief, in accordance with some embodiments;

FIG. 26 shows a view of a collectible and a view of the identification and authentication report of the computerized systems according to an aspect of the disclosure, in accordance with some embodiments;

FIG. 27 shows a method of training one or more AI algorithms to evaluate one or more aspects of a collectible's state of preservation or grade, in accordance with some embodiments;

FIG. 28 shows how an individual collectible may be divided into subregions where measurements or findings (e.g., a mark) in certain regions carry more weight than if present in another region, in accordance with some embodiments;

FIG. 29 shows a schematic of moving components (e.g., X-Y-Z stage or optics) when measurements from a collectible are acquired using a non-contact profilometer, such as a structured light illumination system, in accordance with some embodiments; and

FIG. 30 shows a schematic of moving components (e.g., X-Y-Z stage or profilometer sensor) when measurements from a collectible are acquired using a contact profilometer, such as one or more of an elastomeric sensor, a stylus profilometer, a scanning probe microscope, a coordinate measuring machine, or an atomic force microscope, in accordance with some embodiments.

### DETAILED DESCRIPTION

The following detailed description provides a better understanding of the features and advantages of the inventions described in the present disclosure in accordance with the embodiments disclosed herein. Although the detailed description includes many specific embodiments, these are provided by way of example only and should not be construed as limiting the scope of the inventions disclosed herein.

Although reference is made to evaluating numismatic collectibles such as coins, the presently disclosed systems and methods are useful for evaluating any type of object, such as manufactured parts, automobile parts, aerospace parts, aviation parts, automatic parts, printed parts, minted parts, numismatic collectibles, coins, medals, tokens, ancient specie, bullion, commemoratives, exonumia, paper money, prototypes, trading cards and objects such as insects and plants.

The presently disclosed systems and methods can be used to evaluate manufactured objects. In some embodiments, the manufactured object such as a stamped object shaped with a die, a forged object shaped with compressive force, a high pressure stamping process, e.g. coin striking, embossing, impression die forming, or press forming, for example.

In some embodiments, topology data from a collectible is received, and a report of the collectible is generated in response to the topology data or topography data. In some embodiments, the report may comprise a grading report. The topology data may comprise surface profile data, such as 3D surface profilometry data.

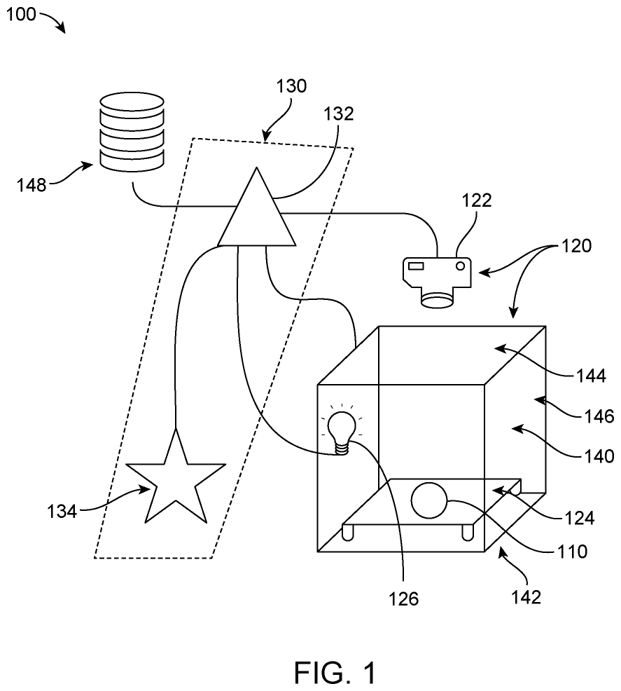

FIG. 1 shows a computerized system 100 to grade a numismatic collectible 110 such as a coin, for example. The computerized system 100 comprises an image acquisition device 120 and a computer system 130. The image acquisition device 120 comprises an imaging device 122, a stage 124, and at least one light source 126 to illuminate at least part of the internal or working space, wherein the stage is optionally within a housing 140 and receives a numismatic collectible 110. In aspects where the at least one imaging device 122 is equipped with its own stage, the imaging device can be isolated from, replace, or supplement the housing 140 and can have its own internal space, light source 126, and one or more sensors for capturing the image of the numismatic collectible 110. In some embodiments, the imaging device 122 comprises a 3D profilometer such as a 3D optical profilometer. In some embodiments, the image acquisition device 120 may comprises the stage 124. The imaging device 122 may comprise any suitable imaging device, such as a plurality of imaging devices, and can be arranged in any suitable configuration. Although reference is made to a 3D optical profilometer, the imaging device 122 may comprise any suitable sensor to acquire data related to the numismatic collectible 110, such as a contact profilometer or a camera, for example. In some embodiments, one or more of the imaging device 122 or the stage 124 may move on an X-Y or X-Y-Z axis to collect data from the most (e.g. a majority) of the external surface numismatic collectible 110. The computer system 130 comprises at least one processor 132, which comprises processor executable computer instructions and at least one output device 134. In some embodiments, the computer system is configured to transmit one or more control signals to the image acquisition device 120.

In some embodiments, the raw data, metadata, analyses, and any additional data from each grading event of a numismatic collectible 110 is stored in a database 148.

In some embodiments, the housing 140 comprises a base 142, a top 144, and a plurality of sidewalls 146. In some embodiments, the base 142 and top 144 are coupled to the plurality of sidewalls 146 such that the base 142 is opposite the top 144. In some embodiments, the base 142, top 144 and plurality of sidewalls 146 define the internal space of the housing 140, in which the numismatic collectible 110 can be placed on the stage 124.

In some embodiments, the collectible is placed on the stage 124. In some embodiments, the collectible is removed from the stage 124. In some embodiments, the collectible is placed on a rotating chuck. In some embodiments, the collectible is removed from a rotating chuck. In some embodiments, the collectible is illuminated with a first illumination condition to acquire a 2D image and illuminated with a second illumination condition to acquire topography data. In some embodiments the object or a source of illumination is moved between illumination with the first illumination condition and illumination with the second illumination condition. The illumination condition can be varied in many ways, and the first illumination condition may comprise illumination to generate a 2D image, and the second illumination condition may comprise structured illumination, for example.

In some embodiments camera image data and profilometer data are acquired. In some embodiments, the camera image data comprises an array of intensity values across a pixelated two dimensional array, and the profilometer data comprising 3D topography data of a surface of the collectible.

In some embodiments, the camera image data is acquired with a first illumination condition and the profilometer data is acquired with a second illumination condition different from the first illumination condition. In some embodiments, the first illumination condition is configured to determine luster from a reflective surface of the collectible. In some embodiments, the data comprises topography data and camera data.

In some embodiments, additional sensors are utilized to collect further data from the numismatic collectible. Examples include but are not limited to glossmeters, spectral or specular reflectance analyzers, x-ray fluorescence (XRF), elemental or metallurgical analysis, etc. In some embodiments, the collectible is placed onto, moved within the area of, or removed from the stage 124 for analysis with these other sensors.

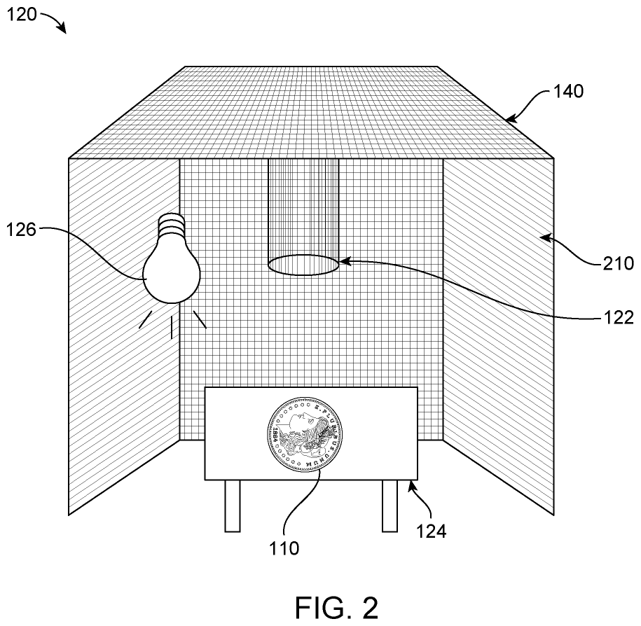

FIG. 2 shows a perspective view of an image acquisition device 120, in accordance with some embodiments. In some embodiments, the imaging device 122 is situated partially or entirely within the internal space of the housing 140. If the housing 140 itself does not sufficiently block exterior light, a covering 210, such as a blackout curtain or other material, devices, and structures known in the art, can also be used with the housing 140 to further ensure that a sufficient amount of exterior light is blocked from entering the internal space of the housing 140 where the numismatic collectible 110 has been placed on stage 124.

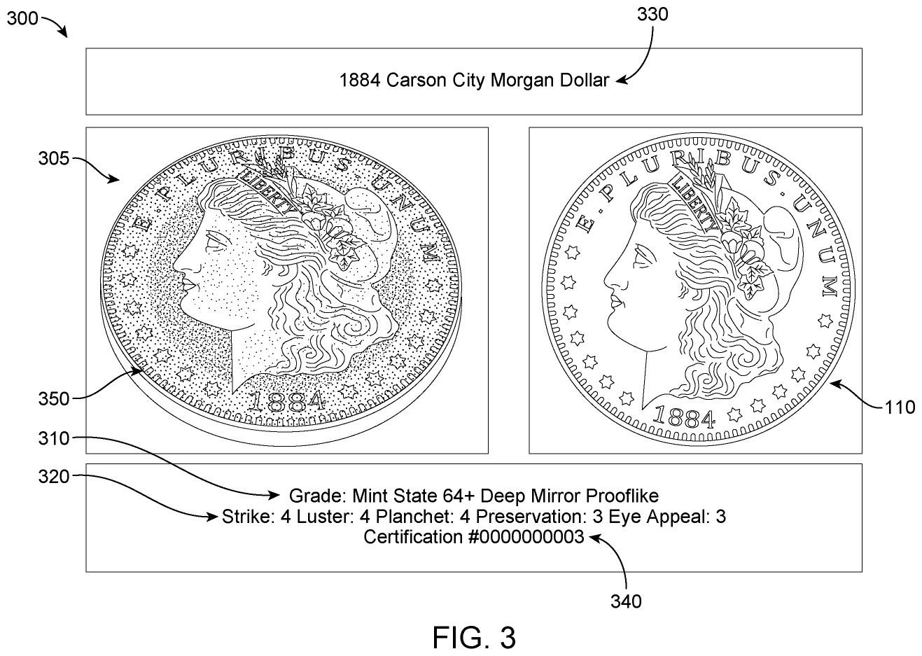

FIG. 3 shows a view of a grade report 300 from the computerized systems, in accordance with some embodiments. In some embodiments, a summary grade report 300 comprises score grade 310, some summary aspects 320 of the measurements, and an overview image of a collectible 110. In some embodiments, identity information 330 of the numismatic collectible is provided with the report 300, such as the type of collectible, e.g. “1884 Carson City Morgan Dollar”. In some embodiments, the grading company certification number 340 is provided with the report, in which certification number 340 is associated with the numismatic collectible and the report in response to the collectible being graded.

In some embodiments, at least a portion of the topography data 305 is also provided in the summary report. The topography data can be provided in one or more of several ways such as, but not limited to, colorized relief data 350. In some embodiments, relief data refers to the physical elevation changes on a surface, such as the microscopic peaks, valleys, roughness, and waviness of the collectible. In some embodiments, the profilometer scans the collectible and acquires grid of X, Y, and Z coordinates. In some embodiments, the “relief data” comprises the Z-coordinates, e.g. the heights or depths, for example. In some embodiments, the processor is configured to apply a color scale, e.g. colormap, to the Z-axis data, which allows the user to visualize the surface topography based on the color map. Alternatively or in combination, the surface relief data 350 may comprise difference data, for example differences between the measured surface of the collectible 110 and a reference surface of a reference collectible, such as the 3D surface topography data of a golden image.

In some embodiments, comparing data of the golden image with the data acquired from the collectible can increase the computational speed of the evaluation and increase the accuracy or repeatability.

By comparing topography data 305 related to at least one of the measured attributes (e.g., marks, toning, strike etc.), or a mathematical transformation of one or more of the measured attributes, for the collectible, the system is able to detect differences among collectibles such as coins, in accordance with some embodiments. In some embodiments, the system is configured identify a specific coin among a plurality of coins of the same type in response to the topography data, such as 3D surface topography data. In some embodiments, the system is configured to detect different individual coins among a plurality of coins, i.e. instances of identical types of coins. Alternatively or in combination, the system can be configured to recognize when the same coin 110 is being graded again. In some embodiments, only the identical coin, assuming it has not been significantly altered since its last grading event, would match a previous grade report 300. In some embodiments, a coin is considered identical, i.e. the same coin, in response to the stored instance of those attributes being close enough to be considered substantially identical. In some embodiments, the system is configured to effectively identify each coin, similarly to a finger print, in response to data as described herein. In some embodiments, this contributor to fingerprinting allows for re-identification of a particular collectible.

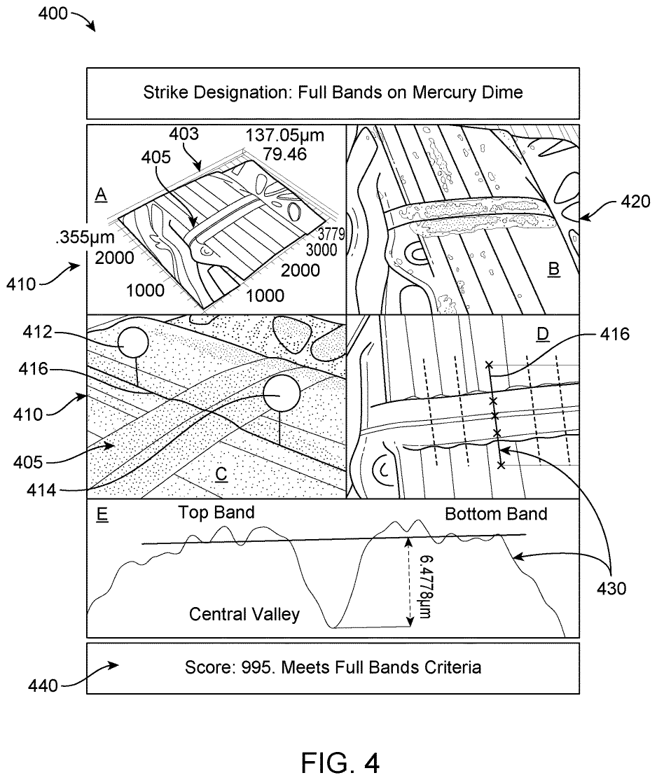

FIG. 4 shows a view of a collectible and a view of strike designation scores of the grade report from the computerized systems, in accordance with some embodiments. In some embodiments, a section of a grading report related to the strike characteristics 405 of a collectible 400, such as a numismatic collectible as described herein. In some embodiments, one way the quality of the strike is assessed for some issues is “strike designations”.

Panel A shows a portion 403 of the 3D topography measurement data 305 from a portion numismatic collectible and a scale. The topography data can be used to evaluate the full bands criteria 410 of the strike characteristic 405, for example.

Panel B shows 3D topography data from prior measurements 420 on other collectibles that can be compared with the current measurement data shown in panel A.

Panel C shows measurement of 3D topography data along a line 416 between a first location of a marker 412 and a second location of a second marker 414. The data along this line can be compared between the current measurement data 410 and prior measurements 420.

Panel D shows line 416 and additional lines that can be used to determine profile data and to evaluate the strike data, e.g. whether the bands are full. At least one measurement 430 is analyzed along line 416 and compared with a reference.

Panel E shows topography data from at least one measurement 430 along line 416. The data shows the differences in depth along the line, and can be used to assess whether the full band criteria has been met. In some embodiments, topography data of a top band, a bottom band, and a valley between the top band and the bottom band are identified in the topography data and compared.

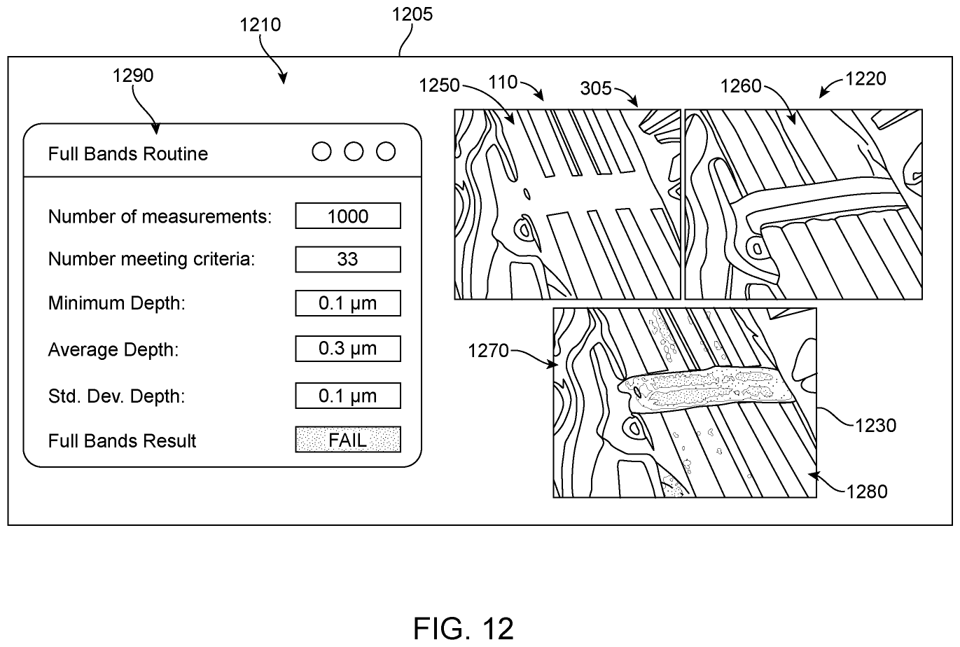

In some embodiments, this example grade report shows the “Full Bands” criteria 410 being assessed for a collectible in the Mercury Dimes series. Another way the quality of the Strike can be assessed for some issues is by comparison of the detail imparted from the striking event and/or the measurement of the height (also referred to as “relief”) of the devices. These measurements can be compared to a golden image 1220 (discussed in FIG. 12), a similar issue deemed “fully struck”, the best-known example for the issue, or in reference to other prior measurements 420. By making at least one measurement 430 of the applicable strike or strike designation region applicable to the issue or series, embodiments of the present disclosure can more consistently, accurately, and reproducibly determine the quality of strike and give it a rating 440.

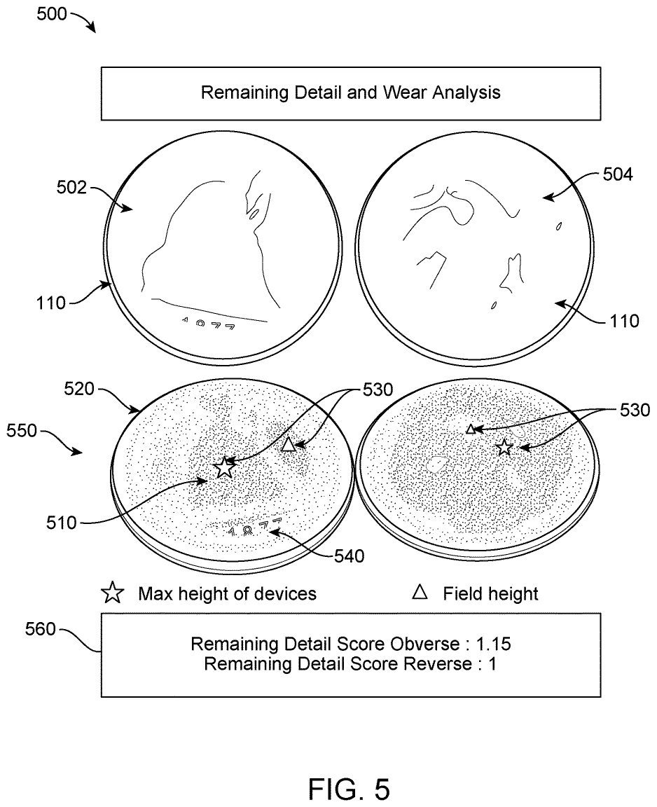

FIG. 5 shows a view of a first side 502 and a second side 504 of a collectible 110 and a view of the detail and wear scores of the grade report from the computerized systems, in accordance with some embodiments. In some embodiments, a grade report provides one or more scores of related to a wear analysis 500. In some embodiments, the measurements include but are not limited to one or more of a comparison with data such as 3D topography data of a golden image (see FIG. 12, reference 1220), analysis of the missing/remaining details 510, measurements of the rim 520, the remaining difference between the fields and the devices 530, or the remaining height of specific detail(s) 540. This example shows a highly worn collectible 110 along with a subset of the profilometry measurements 550 from the first side 502 and the second side 504 that are performed to assign the wear scores 560.

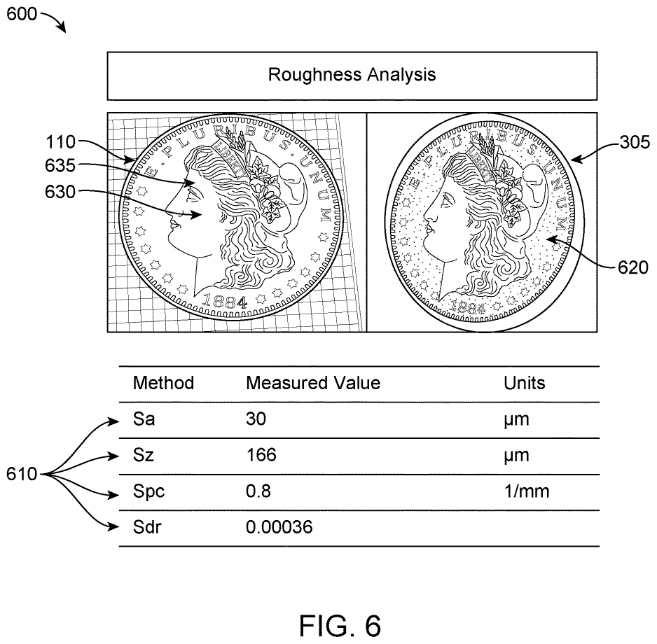

FIG. 6 shows views of a collectible 110 and a view of the roughness scores of the grade report from the computerized systems, in accordance with some embodiments. In some embodiments, the roughness analysis 600 is based on profilometry data as described herein, such as topography data, for example 3D topography data 305 of one or more sides of the collectible 110. In some embodiments, individual roughness measurements 610 are performed to obtain profilometry data 605 for various sections of the collectible 110. In some embodiments, the roughness measurements are determined for one or more fields 620. The one or more fields 620 may comprise a flat background area around the devices 630, e.g. the main design element, such as a head 635. In some embodiments, roughness measurements can be a component of determining aspects of the coins grade including but not limited to one or more of the luster type, planchet quality, or state of surface preservation. For example, a new set of freshly polished dies may initially produce coins with mirror finish field 620 and then as die wear (aka die erosion) occurs as part of normal die life, the fields of the coin may become more “lustrous” and scatter light in what can be referred to in the art as a “cartwheel” effect.

In some embodiments, the processor is configured to determine luster from the topography data associated with roughness and light scatter. In some embodiments, the processor is configured to determine that the coin has a mirror finish in response to the 3D topography data. In some embodiments, the processor is configured to determine that a freshly polished die was used to manufacture a coin in response to topography data because the die starts out producing mirror finish coins. In some embodiments, the processor was configured to determine that the coin was manufactured with a worn die, because as die wear (aka die erosion) occurs as part of normal die life, the fields of the coin become “lustrous” and scatter light in what is referred to as a “cartwheel” effect. The 3D topography data as described herein can be provided to an AI model to determine the lustrousness and light scatter, e.g. cartwheel effect, in response to the topography data, for example.

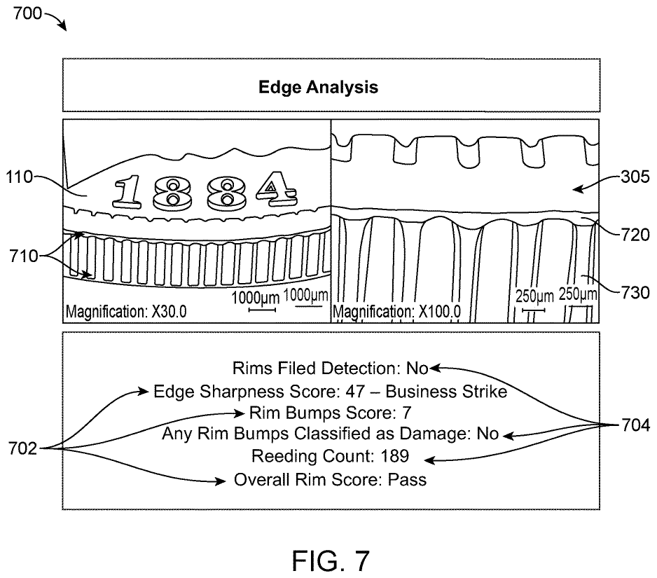

FIG. 7 provides an example of the edge analysis report 700 that provides scores 702 and information 704 about the edge 710 of the collectible 110. For example, the sharpness of the rims 720 is one indicator of whether the object was fabricated as a “business” or “proof” issue. Other examples include determining whether the rims 720 have been filed, assessing the degree to which the rim has received “bumps” or “hits” and if any should be classified as damage, and the number of reeds 730 on the edge of the coin (routinely used for identification and authentication purposes). This analysis can be performed with the digital profilometry data, such as 3D topography data 305. In some embodiments, the 3D topography data for the edge is collected by rotating the collectible 110 under or above the imaging device 122. In some embodiments, the 3D topography data is compared with the golden image data to perform the edge analysis as described herein.

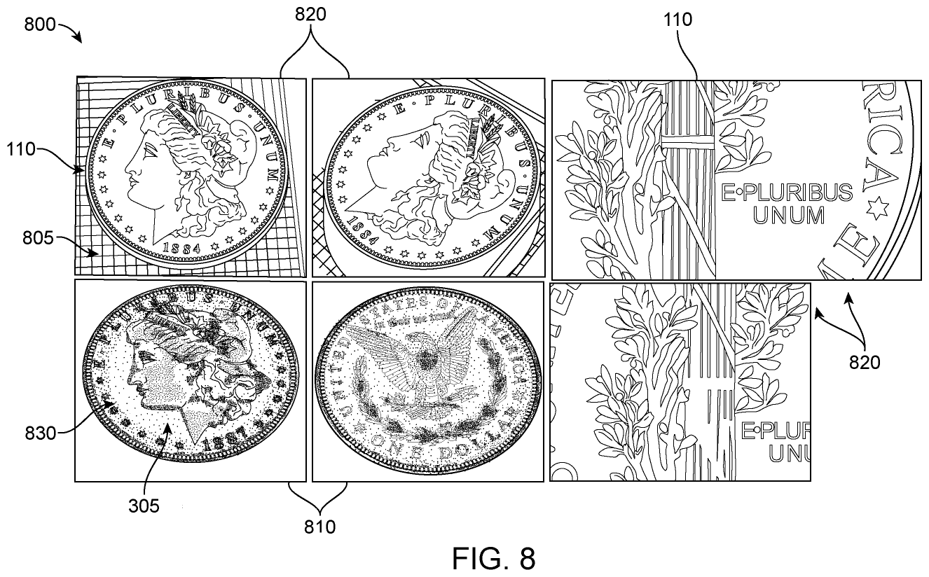

FIG. 8 shows a digital twin 800 of a numismatic collectible item 110, in accordance with some embodiments. In some embodiments, the digital twin 800 comprises profile data, such as 3D topography data 305 as described herein. In some embodiments, the digital twin comprises a highly accurate, measurable, and mathematically precise virtual representation of the object such as the numismatic collectible item 110. In some embodiments, the digital twin 800 increases the reliability and accuracy of the evaluation. In some embodiments, the digital twin decreases the speed of the computations utilized to perform the evaluation.

In some embodiments, the measured data of the object comprises a resolution of at least 100 pixels (or voxels) in each direction, although the resolution can be at least one thousand in each direction, e.g. at least one megapixel resolution. In some embodiments, the resolution is related to the number of data points in each direction of the measured object. The number of pixels of the measured object far exceeds the amount of data that can be performed as a mental process and improves the accuracy of the evaluation. In some embodiments, the spatial resolution of the measured object is finer than 100 μm, for example finer than 50 μm, or 25 μm, or 10 μm, for example. This spatial resolution of the measured object can improve the accuracy of the measurement. In some embodiments, the depth resolution of the measured object is finer than 25 μm, for example finer 10 μm, or 5 μm, or 2.5 μm, 1 μm, 0.5 μm, 0.25 μm or 0.1 μm. This depth resolution of the measured object can improve the accuracy of the measurement. In some embodiments the measurement data of the object comprises a 3D point cloud, for example a point cloud of a 3D surface arranged with pixels or a 3D point cloud arranged with voxels, for example. In some embodiments, this association of additional data of the measured object at each surface location of a plurality of points improves the accuracy of the evaluation of the object such as a collectible.

In some embodiments, each location of a plurality of locations of the measurement data of the evaluated object such as a digital twin or point cloud data comprises a plurality of values related to the evaluation of the object at that location. For example, each location of the plurality of locations may comprise a plurality of values related to a plurality of process such as two or more of identification data, strike data, luster data, wear data, eye appeal data, marks data, a visual contrast data, e.g. data, no grade, or toning data, for example. In some embodiments, each of the plurality of locations of the measurement data comprises data related to three or more of identification data, strike data, luster data, wear data, eye appeal data, marks data, visual contrast data, e.g. cameo data, no grade data, or toning data, for example. In some embodiments, each of the plurality of locations comprises measurement data related to four or more of identification data, strike data, luster data, wear data, eye appeal data, marks data, visual contrast data, e.g. cameo data, no grade, or toning data, for example. In some embodiments, each of the plurality of locations comprises measurement data related to five or more of identification data, strike data, luster data, wear data, eye appeal data, marks data, visual contrast data, e.g. cameo data, no grade, or toning data, for example. In some embodiments, each of the plurality of locations comprises measurement data related to six or more of identification data, strike data, luster data, wear data, eye appeal data, marks data, visual contrast data, e.g. cameo data, no grade, or toning data, for example. In some embodiments, each of the plurality of locations comprises measurement data related to identification data, strike data, luster data, wear data, eye appeal data, marks data, visual contrast data, e.g. cameo data, no grade, and toning data, for example.

In some embodiments, the digital twin comprises a resolution of at least 100 pixels (or voxels) in each direction, although the resolution can be at least one thousand in each direction, e.g. at least one megapixel resolution. In some embodiments, the resolution is related to the number of data points in each direction, for example along a grid or array 805. The number of pixels far exceeds the amount of data that can be performed as a mental process and improves the accuracy of the evaluation. In some embodiments, the spatial resolution is finer than 100 μm, for example finer than 50 μm, or 25 μm, or 10 μm, for example. This spatial resolution can improve the accuracy of the measurement. In some embodiments, the depth resolution is finer than 25 μm, for example finer 10 μm, or 5 μm, or 2.5 μm, 1 μm, 0.5 μm, 0.25 μm or 0.1 μm. This depth resolution can improve the accuracy of the measurement. In some embodiments the digital twin comprises a 3D point cloud, for example a point cloud of a 3D surface arranged with pixels or a 3D point cloud arranged with voxels, for example. In some embodiments, this association of additional data at each surface location of a plurality of points improves the accuracy of the evaluation of the object such as a collectible.

In some embodiments, each location of a plurality of locations of the reference data, e.g. reference data corresponding to an ideal object, comprises a plurality of values related to the evaluation of the object at that location. The reference data of the ideal object may comprise reference digital twin data or reference point cloud data of the ideal object, e.g. gold standard data, for example. In some embodiments, the reference data comprises a resolution and data structure that is similar to the measurement data, such as the measured digital twin or point cloud of the object. In some embodiments, each of the plurality of locations of the reference data, e.g. reference digital twin reference data or reference point cloud data, comprises data related to two or more of identification data, strike data, luster data, wear data, eye appeal data, marks data, visual contrast data, e.g. cameo data, no grade data, or toning data, for example. In some embodiments, each of the plurality of locations of the reference data, e.g. reference digital twin reference data or reference point cloud data, comprises data related to three or more of identification data, strike data, luster data, wear data, eye appeal data, marks data, visual contrast data, e.g. cameo data, no grade data, or toning data, for example. In some embodiments, each of the plurality of locations of the reference data, e.g. reference digital twin reference data or reference point cloud data, comprises data related to three or more of identification data, strike data, luster data, wear data, eye appeal data, marks data, visual contrast data, e.g. cameo data, no grade data, or toning data, for example. In some embodiments, each of the plurality of locations comprises reference data related to four or more of identification data, strike data, luster data, wear data, eye appeal data, marks data, visual contrast data, e.g. cameo data, no grade, or toning data, for example. In some embodiments, each of the plurality of locations comprises refence data related to five or more of identification data, strike data, luster data, wear data, eye appeal data, marks data, visual contrast data, e.g. cameo data, no grade, or toning data, for example. In some embodiments, each of the plurality of locations comprises reference data related to six or more of identification data, strike data, luster data, wear data, eye appeal data, marks data, visual contrast data, e.g. cameo data, no grade, or toning data, for example. In some embodiments, each of the plurality of locations comprises reference data related to identification data, strike data, luster data, wear data, eye appeal data, marks data, visual contrast data, e.g. cameo data, no grade, and toning data, for example.

In some embodiments, each point of the dataset, e.g. the point cloud, comprises additional data in combination with the spatial data. The data may comprise color data, e.g. Red Blue and Green (RGB data), smoothness data, reflectance data, specular reflectance and scatter data, for example. In some embodiments, the color data comprises three channels associated red, blue and green. Each channel may comprise eight bit resolution or greater, for example. The reflectance data may comprise data related to the reflection of light, such as the amount of light reflected (e.g. the albedo), the specular component (mirror like) and the scattered component (non-mirror like). This reflectance data is related to properties of the collectible, such as luster. In some embodiments, this association of topography data with color data, reflectance data for each point in the can increase the accuracy of the evaluation.

The digital twin may comprise any suitable data structure, such as one or more of 3D scan data, e.g. a point cloud, a polygon mesh, or a voxel grid. In some embodiments, the digital twin comprises a substantially exact geometric and dimensional representation of the object such as a numismatic collectible, captured using high-precision 3D measurement tools such as laser scanners, structured light scanners, Coordinate Measuring Machines (CMMs), or Industrial CT scanners, and other approaches as described herein, for example. In some embodiments, the digital twin comprises measurement data with a data structure, and the reference digital twin comprises reference data with a substantially similar data structure.

In some embodiments, the shape and dimensional data (the geometry/topography) form the foundational data, or “skeleton” of a digital twin. In some embodiments, the digital twin, comprises a multi-layered data structure that maps various types of information onto the 3D spatial data. In some embodiments, the digital twin comprises a metrological digital twin that includes a plurality of layers of data.

In some embodiments, the digital twin comprises surface properties in addition to physical coordinates. In some embodiments, the digital twin has data related to how the surface behaves and appears. The digital twin may comprise any of the following data:
1) Color and Texture (RGB Data). In some embodiments, photogrammetry and structured light scanners capture high-resolution color maps and project them onto the 3D mesh. This is helpful for inspecting visual defects like burn marks, rust, or paint discoloration.
2) Surface Roughness & Micro-Topography. In some embodiments, high-precision metrology tools like white light interferometers or laser profilometers can capture the microscopic finish of a surface as described herein. In some embodiments, the digital twin can include data on friction coefficients or roughness averages (Ra/Rz), which can be related to luster, marks, or wear.
3) Reflectivity and Gloss (BRDF). In some embodiments, optical metrology can capture how light scatters off the surface (Bidirectional Reflectance Distribution Function). This is heavily used in automotive manufacturing to ensure car panels have the exact same paint finish and gloss level.
4. Internal and Material Properties. In some embodiments, the digital twin is generated using Industrial CT (Computed Tomography) scanning, which goes beyond the surface and includes the inside of the object.
5. Manufacturing Traceability and Metadata. In some embodiments, a digital twin acts as the permanent identifier, e.g. unique ID, for a specific physical collectible. The digital twin can be tagged with: a) machine parameters: the settings of the machine that made it (e.g., the temperature or pressure); or b) Lineage Data: serial numbers, batch numbers, the specific operator on shift, and the exact date and time it was measured.

The data of the digital twin 800 can be used in many ways as described herein. In some embodiments, the computer is configured to provide a user interface to allow the user to view the digital twin 800 in any suitable way. In some embodiments, the digital twin 800 can be viewed with views, such as 3D views. The views can be provided both with and without overlays and/or backgrounds, in accordance with some embodiments. In some embodiments, the digital twin 800 of the numismatic collectible 110 can be viewed in a first view 810 with a profilometry color overlay and in a second view 820 without the profilometry color overlay, for example. The second view may comprise a traditional image from a camera, for example. Other overlays or views including but not limited to one or more of a full 3-dimensional rotational view, a point cloud view, a mesh view, a CAD model view 830, or different color overlays. Examples of these views are shown in FIG. 8. In some embodiments, the user interface is utilized by a human grader or human reviewer counterpart for viewing or analysis of the digital twin for any of but not limited to providing input or additional data about the collectible, ensuring correct analyses, or manual adjustments.

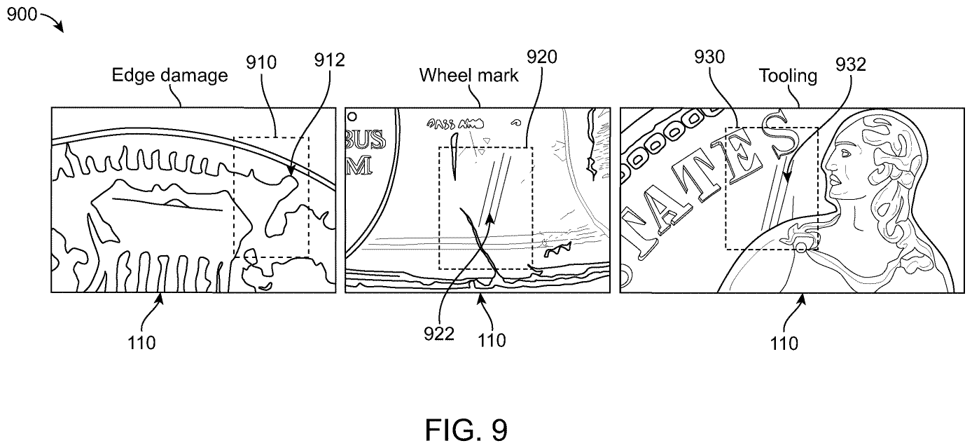

FIG. 9 provides examples of different types of “No Grades” (i.e., forms of damage, manipulation, authenticity concerns, etc.) 900 detected by computer analysis of the images and measurements, such as 3D measurement data, taken from the object such as the numismatic collectible 110. In some embodiments, the area with the damage is detected, for example based on a comparison of 3D data with the golden image data. In some embodiments, the area with the damage is shown in a bounding box or with keypoints, and the area with the damage can be reviewed during the grading process by experts and/or presented as part of the grading report. In some embodiments, the keypoints or bounding box identifies the area with damage to facilitate review. The example of edge damage identified with keypoints or a bounding box 910 shows a section of the collectible's edge where the hit has caused excessive damage 912 to the denticles. The example of the wheel mark identified with keypoints or a bounding box 920 details a section of the collectible where the burn mark pattern 922 from a rubber wheel is evident. The example of tooling identified with key points or a bounding box 930 shows a section of a collectible where the fine scratches 932 from an attempt to repair or enhance the collectible are detected. Work in relation to the present disclosure suggests that reporting the location(s) and type(s) of damage detected may help alleviate the “black box” nature of grading, and may build confidence in the marketplace that a collectible has been accurately assessed for state of preservation, which can be related to monetary value.

Although reference is made to a collectible, the no grade algorithm can be used to evaluate any object as described herein. In some embodiments, the no grade algorithm can improve the accuracy of the grading, because the trained AI algorithm has the option of reporting no grade, and is not forced to complete and provide grading with other processes and algorithms and described herein, which may also improve the efficiency of the computing process, for example. The no grade algorithm can be used with any object as described herein.

In some embodiments, an output image is generated to provide the view of the collectible. In some embodiments, the output image identifies a feature related to the grade report, such as scratches or other defects. In some embodiments, a bounding box or keypoints have been overlaid on the output image to identify the feature, for example. The output image with the keypoints or bounding box can be included in the report.

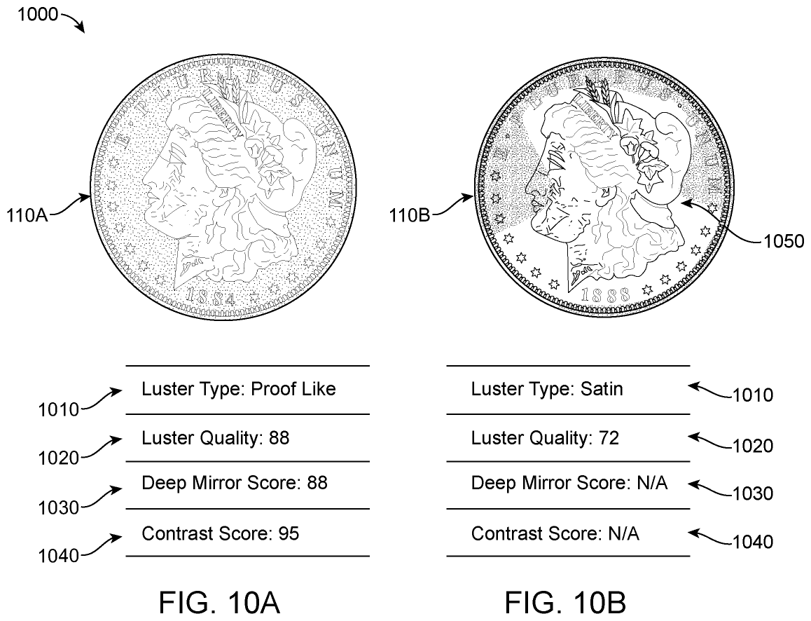

FIGS. 10A and 10B provide partial examples of score reports related to the luster analysis 1000 of a collectible 110, such as coins. In some embodiments, high level factors of the analysis are the type of luster 1010 and the quality 1020 of the luster, according to which type of luster is present. In some embodiments, sub-routines can be activated to further score the luster as appropriate. For example, FIGS. 10A and 10B show the deep mirror fields score 1030 and contrast score 1040 between the fields and devices score for the collectible 110A with proof-like luster, both of which are not applicable to the other collectible 110B shown with Satin luster. Examples of suitable technologies for obtaining luster data in accordance with the present disclosure include optical measurements, evaluation of a reflected pattern's readability (or trueness to the original pattern or text) on the surface (e.g., the fields 1050) of the collectible 110 at various distances, a glossmeter (operating at one or more angles and with or without haze), or spectral reflectance measurements. In some embodiments, the luster data comprises specular reflectance data. In some embodiments, the specular reflectance data is generated with one or more components of a commercially available glossmeter or DOI meter such as the HORIBA IG-340 or DeFelsko Positector GLS. In some embodiments, the luster data is collected utilizing one or more components of commercial systems that capture gloss, waviness, orange peel, sparkle, and graininess, such as camera-based appearance analyzers manufactured by Rhopoint Aesthetix, for example. Alternatively or in combination, the luster data can be acquired with a non-commercial specular reflectance apparatus that rasters a beam across the surface and measures reflected energy.

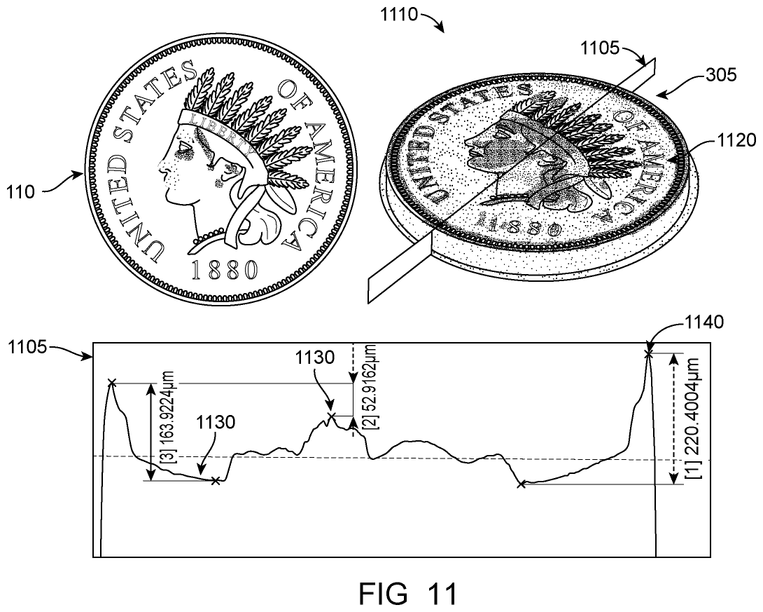

FIG. 11 shows a view of a collectible 110 and a view of the strike and method of manufacture analysis from the computerized system 100. In some embodiments, certain characteristics of numismatic collectibles, such as full strikes and sharp rims on proof coinage compared to business strikes, are useful toward determining the method of manufacture of a coin. In some embodiments, topology data 1120, such as the relationship among features of the collectible, are derived from topography data 305. In some embodiments, the collectible 110, such as the Indian head cent 1110, is determined by the computerized system to be a proof issue coin from the topology data 1120 showing it is fully struck (e.g., height difference of the fields to the peak of portrait 1130) with sharp rims between the denticles and edge of the collectible (i.e., the sharp peak 1140 shown in the slice 1105 of the topology data plotted). Alternatively or in combination, the collectible 110, such as the Indian head cent 1110, is determined by the computerized system to be a proof issue coin from the topography data 305 showing it is fully struck (e.g., height difference of the fields to the peak of portrait 1130) with sharp rims between the denticles and edge of the collectible (i.e., the sharp peak 1140 shown in the slice 1105 of the data plotted).

FIG. 12 shows a user interface 1210 configured to allow a user to interact with the data of the numismatic collectible and to provide images on a display, in accordance with some embodiments. In some embodiments, one or more of a view 1250 of data from a collectible such as topography data 305, a view 1260 of data from a golden image 1220 such as topography data, and a view 1270 of the comparison data 1280 can be generated and shown on the display with the computerized system.

The human-computer interface 1210 can be configured to provide human-in-the-loop, human-on-the-loop, and other human interaction or intervention with the computerized grading system 100. In some embodiments, interface 1210 allows the user to interface with the computer system, such as with a graphical user interface, e.g. a touch screen display, to review the measurements, analyses, etc. and make corrections or adjustments if appropriate. In some embodiments, the interface 1210 provides a view 1270 of the comparison data 1280 for the comparison of the data 305 of the collectible 110 and the data of golden image 1220. In some embodiments, the comparison data 1280 comprises a comparison between the image data 305 of the collectible and a previously graded collectible. In some embodiments, the difference between the two sets of data is presented as a new image 1230 in this example.

In some embodiments, the golden image 1220 comprises golden image data of a golden digital twin. In some embodiments, the golden digital twin comprises digital twin data of the golden image. In other words, the golden digital twin comprises a digital representation of a perfect collectible, e.g. a coin, which can be used as a reference standard compared to the digital twin of the collectible being evaluated.

In some embodiments, the user interface is configured to provide data 1290 on the display 1205 that allows the user to view the results of the analysis. In some embodiments, the data 1290 comprises one or more of a type of routine, e.g. full bands, a number of measurements for the routine, e.g. 1000, a minimum depth of a feature such as a band, e.g. 0.1 μm, an average depth of the feature, e.g. 0.3 μm, a standard deviation of the depth of the feature, e.g. 0.1 μm, and the result of the text, e.g. a pass or a fail.

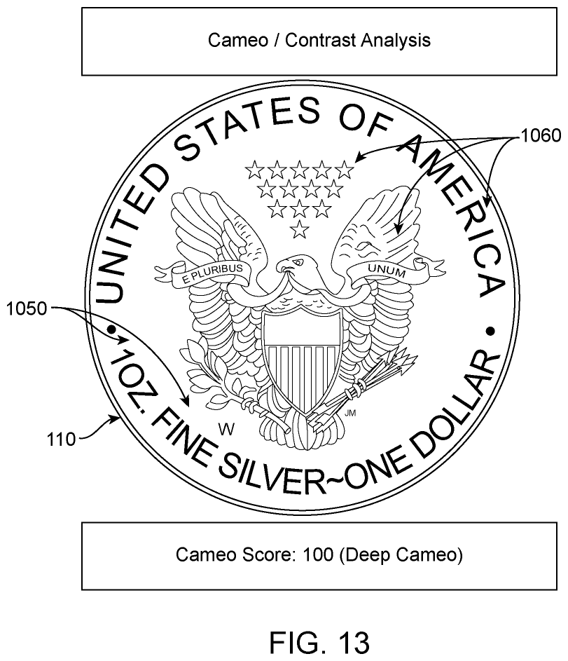

FIG. 13 shows a view of a collectible, and a view of the cameo grading scores of the grade report from the computerized system, in accordance with some embodiments. In some embodiments, the computerized system provides one or more score reports for the contrast (aka cameo effect) between the fields 1050 and the devices 1060 of the collectible 110, such as a coin. In some embodiments, the cameo effect refers to the visual contrast between the raised design elements, e.g. the devices, and the flat background areas, e.g. the fields, of a collectible such as a coin. In some embodiments, the fields 1050 comprises mirror fields. In some embodiments, the mirror fields comprise substantially flat, background areas of the collectible such as a coin that are so highly polished and reflective that they appear and function as a mirror. In some embodiments, such as when dealing a with reverse proof collectible, the devices are reflective such that they appear and function as a mirror. While at least one comparison can be made, it can be helpful for substantially the entirety of the devices and fields to have strong contrast to increase, e.g. maximize, the contrast score.

Although reference is made to a collectible, the cameo algorithm can be used to evaluate the visual contrast of any object as described herein. The visual contrast between the raised design and the background, e.g. fields, can be helpful to evaluate any object as described herein.

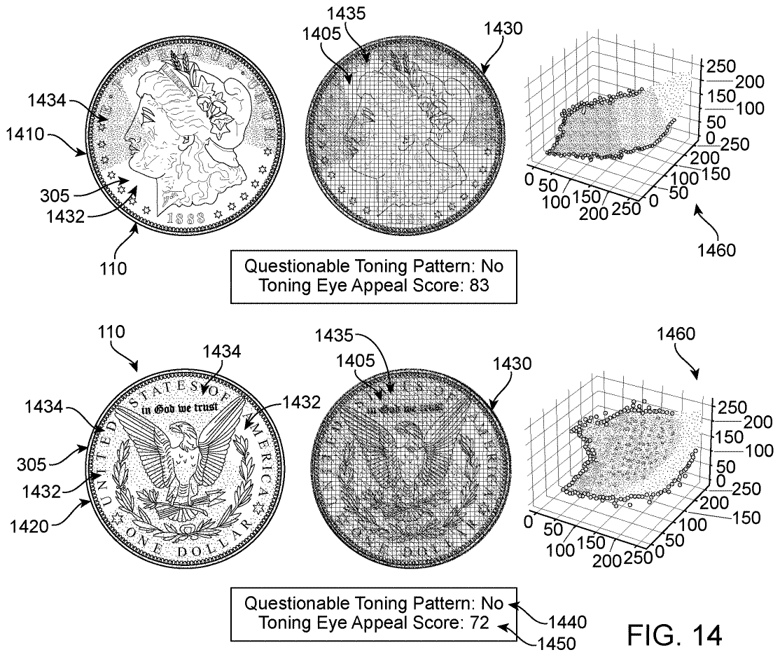

FIG. 14 shows a view of the obverse and reverse of a collectible, and a view of the toning grading scores of the grade report from the computerized system, in accordance with some embodiments. In some embodiments, score reports and analysis data related to the toning of a coin are provided on the user interface on the display. In some embodiments, the obverse side 1410 and reverse side 1420 of the example collectible 110 are displayed, for example on the user interface of the computer display as described herein. In some embodiments, the collectible 110 has regions with toning 1432 on the surface, and regions with a lack of toning 1434, e.g. shiny regions. In some embodiments, the user interface displays profile data such as 3D topography data 305 on each side of the collectible 110 on the display as described herein. In some embodiments, the toning algorithm(s) is configured to flag an overall toning pattern 1430 or parts of a toning pattern that may indicate that a coin has been altered in order to artificially raise its grade. In some embodiments, the toning pattern is located on a grid 1435, in which each area, e.g. pixel of the grid 1435 comprises a toning value 1405. In some embodiments, the toning value 1405 comprises an RGB value of a pixel. In some embodiments, the toning pattern 1430 comprises a spatial relationship with respect to the coin in at least x and y axes, which may be registered with the 3D topography data, for example. In some embodiments, the toning pattern 1430 may include z information, such as z-information related to toning and 3D surface profile topography in a combined data set, for example. In some embodiments, the computer system is configured to analyze the toning pattern to inspect for an alteration of the coin. If the toning is not flagged as questionable as shown at output 1440, the attractiveness of the toning are shown at output 1450. The attractiveness of the toning can be based on one or more of colors present, the evenness of the toning, fingerprints in the toning, or the amount of the coin toned, and other parameters. In some embodiments, the toning is evaluated as part of determining the overall score of the coin. In some embodiments, red, blue and green (RGB) color plots 1460 show the colors present on the obverse and reverse of the example collectibles but not their spatial relationships, for example. In some embodiments, the RGB color plots are input to the computer system to determine the toning grading scores. Alternatively or in combination, the RGB color plots 1460 can be combined with 3D surface profile data 305 and input into the computer system to determine the toning grading scores.

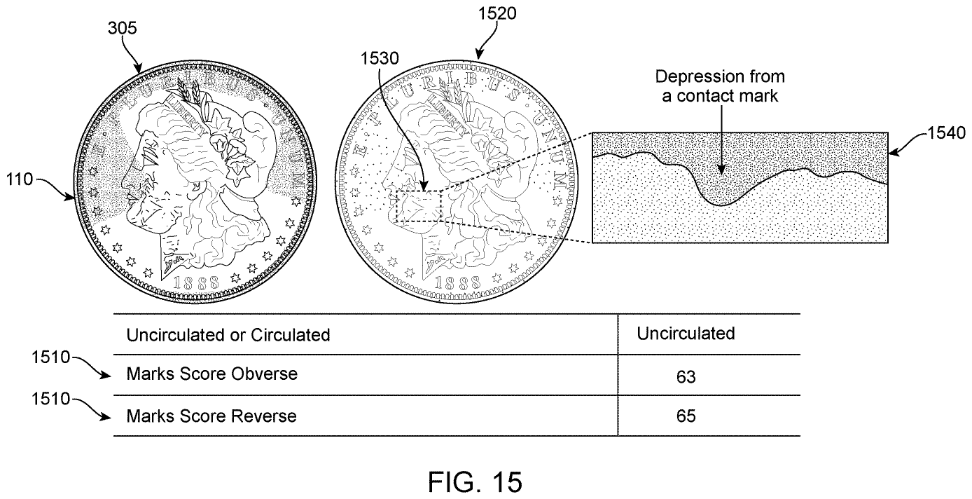

FIG. 15 shows a view of a collectible 110 and 3D topography data 305, a view of the output 1520 of the marks analysis routine, and a view of the marks grading scores 1510 from the computerized systems, in accordance with some embodiments. In some embodiments, the marks are identified with keypoints or a bounding box 1530 shown overlaid on the output 1520 of the marks analysis. In some embodiments, the score reports show the marks component of the grading scores for the grading report. In some embodiments, there are many different forms of damage that fall under marks, which can be measured, and at least some of the algorithm(s) as described herein will be able to classify and/or categorize marks. In some embodiments, the degree of damage and the location of the mark on the numismatic collectible 110 will be used by one or more algorithms to determine the severity of the marks. In some embodiments, the marks will detract from the score 1510 for obverse and the reverse. In some embodiments, depending on the severity of the marks, the marks may potentially result in a “No Grade” result for some types of and/or severe marks. In some embodiments, example 2D profilometry data 1540 across a singular contact mark or hit is magnified and shown on the display with the user interface. Although reference is made to 2D profilometry data, in some embodiments the marks are evaluated with 3D profilometry data such as 3D topography data, for example.

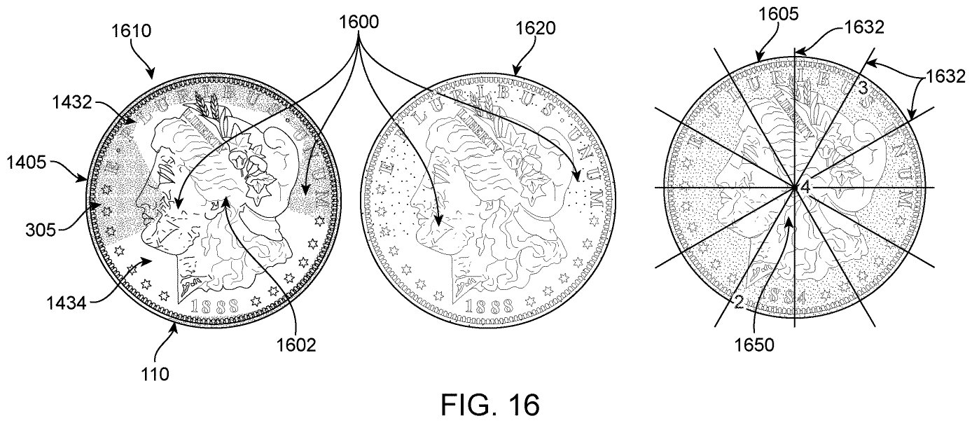

FIG. 16 shows physical characteristics 1600 of a collectible 110 that can be used to uniquely identify the collectible, in accordance with some embodiments. The characteristics 1600 may comprise unique distinctive imperfections and other characteristics as described herein, which allow the collectible to be uniquely identified and distinguished from other collectibles of the same type. In some embodiments, the user interface can be configured to provide a view 1610 of data of the collectible 110, a view 1620 of the output data, such as output data of the marks analysis routine, and a view of output unique identification data 1605 from one or more processing routines to generate information beneficial for unique identification, such as a plurality of line measurements 1632, e.g. several line measurements. In some embodiments, the unique identification data 1605 comprises data that is unique to collectible, even as compared with other collectibles of the same type of collectible, such that the collectible 110 can be uniquely identified, similarly to a finger print. In some embodiments, the computerized system is configured to provide a partial summary of the analysis from the computerized system that provides data akin to a digital finger print of the collectible, e.g. fingerprinting, in accordance with some embodiments.

In some embodiments, the system configured to generate unique identification data, e.g. a “fingerprint”, for each numismatic collectible 110 in response to the unique, distinctive imperfections and other characteristics 1600. In some embodiments, the unique physical characteristics 1600 comprise as-made and post-fabrication characteristics, which are unique to each collectible and can be difficult to replicate. In some embodiments, the as made unique physical characteristics 1600 comprise one or more of strike weakness 1602, planchet flaws, die varieties, or other errors, as will be understood by one of ordinary skill in the art. In some embodiments, the post fabrication unique characteristics 1600 comprise one or more of marks, a toning value 1405, toning 1432, lack of toning 1434, fingerprints, environmental damage, or manipulation, as will be understood by one of ordinary skill in the art. In some embodiments, similarity analysis to previously graded collectibles can be performed. In some embodiments, the identification data is used to authenticate a collectible 110 if it has been previously graded, for example. This can be helpful to confirm that the collectible is not a fraudulent duplication of an authenticated collectible for example.

In some embodiments, the previously collected data can be used to determine if the collectible 110 has changed from a prior evaluation. The previously collected data may comprise any data as described herein such as 3D surface topography data, luster, or toning, for example. In some embodiments, the data to evaluate change comprises data related to fingerprinting. In some embodiments, the data comprises mathematical transform data, for example. This data can be helpful to one or more of authenticate, assess, detect change, manipulation, alteration, detect a counterfeit or a group of counterfeits. In some embodiments, change is detected in response to new contact marks. In some embodiments, an alteration can be detected in response to a previously present hole having been plugged. In some embodiments, a counterfeit or a group of counterfeits can be detected by detecting the same pattern of marks or defects on a plurality of (e.g. multiple) collectibles. In some embodiments, the same pattern of marks of the counterfeits comprise “repeating depressions” as is known on one of ordinary skill in the art in the numismatics industry, for example.

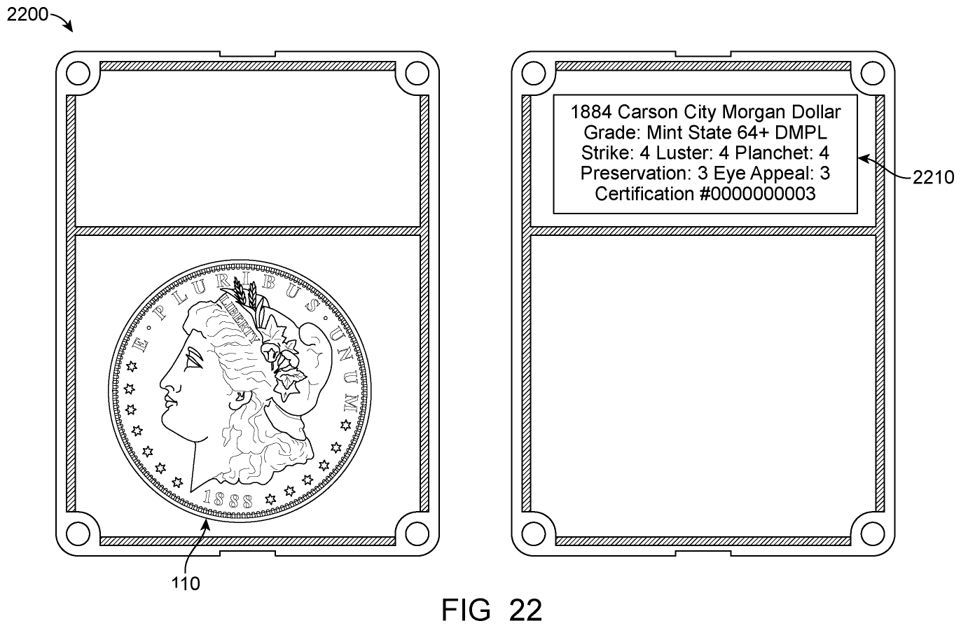

The finger printing data of the collectible 110 can be configured in any suitable way. In some embodiments, the data comprises an array of data such as a radial array of data or two dimensional array of data with values at each point, both of which can be similar to finger print data. The data may comprise one or more of 3D surface topography data, luster data, or toning data, at each point, e.g. each pixel, of the data, such as data of a digital twin. In some embodiments, one or more radial measurements from a central point 1650, such as a plurality of radial measurements 1632 can be used. Alternatively, surface topography data, luster, and toning can be used to generate a digital fingerprint of the coin for example with a two dimensional array of data combining topography data at each location and luster and toning at each location. The array may comprise a radial array, e.g. radial coordinate and angle, or a rectangular array, e.g. row and column coordinates such as xy Cartesian coordinates, for example. An example of the types of features, defects, and mathematical methods that may be used are shown in FIG. 16. This “fingerprint” analysis may be performed on a collectible that is raw, e.g. exposed to the environment, or in a holder as described herein, for example with reference to slab 2200 of FIG. 22.

The presently disclosed systems and methods are well suited for evaluating raw collectibles as well as collectibles that have been placed in one or more of a capsule holder or slab. In some embodiments, the collectible can be evaluated while placed in the one or more of the capsule, holder or slab. In some embodiments, the collectible is not removed from the capsule, holder, or “slab” when evaluated, for example.

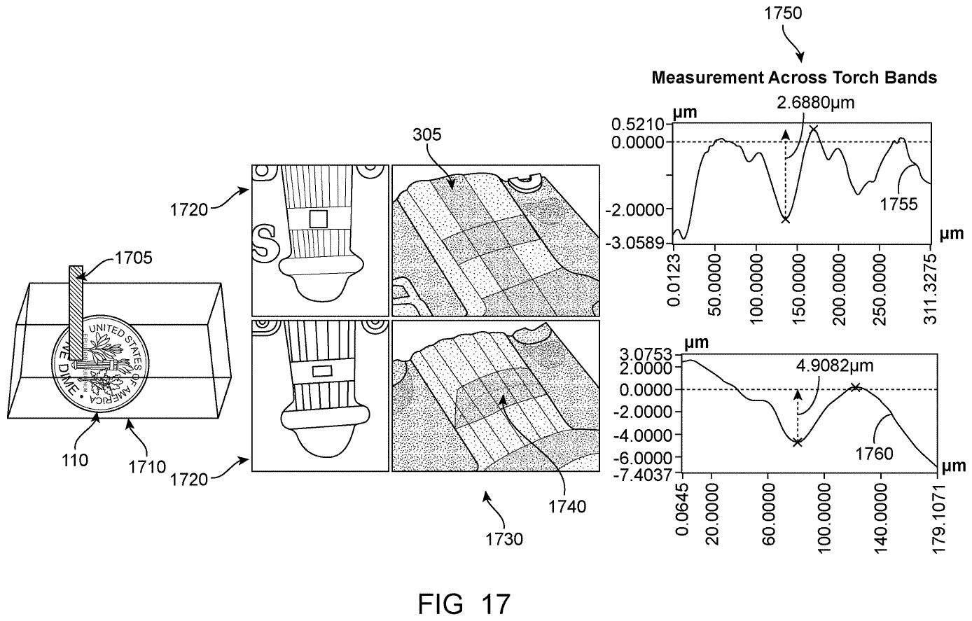

FIG. 17 is a schematic illustration of a collectible 110 being evaluated through an enclosure 1710. In some embodiments, topography data 305 is acquired through the enclosure as described herein. In some embodiments, the acquired data 1720 includes an optical image, such as a camera image, and 3D profilometry measurement data 1730 such as 3D measurement data from a laser profilometer. In some embodiments, the 3D profilometer comprises scanning laser beam 1705. In some embodiments, acquired data 1720 is processed to generate 3D profile data 1730. In some embodiments, the measurement data is converted to a 3D profile.

In some embodiments the 3D profile data is generated for all or part of the collectible, such as the region overlapping the “Full Torch” strike designation area 1740, for example. The topography data of the strike designation area 1740 can be evaluated with the 3D profile data 1730. The profile data can be measured across the torch bands 1750 as shown with profiles 1755, 1760, respectively. In some embodiments, the full strike designation area 1740 of the collectible 110 comprises a weak struck profile 1755 for the collectible 110. Alternatively, the full strike designation area 1740 may comprises nearly full struck profile 1760. For example, the profile 1755 shows a depth of 2.6880 μm, and the profile 1760 shows a depth of 4.9082 μm. While any suitable collectible may be used or analyzed, in some embodiments the collectible comprises a Roosevelt dime.

In some embodiments, the markedly small difference, particularly for the human eye and manual grading, is shown by the difference of only a few microns (~2 microns) between receiving the strike designation or not, for example. In some embodiments, the acquisition of some or all of the images and/or measurement data through a slab 2200, capsule, or other holder can be obtained with profilometry measurements such as a laser-based profilometry system and other approaches as described herein, for example.

Examples of suitable enclosures 1710 include a capsule, a slab 2200, or a container. The slab 2200 is described with reference FIG. 22, for example.

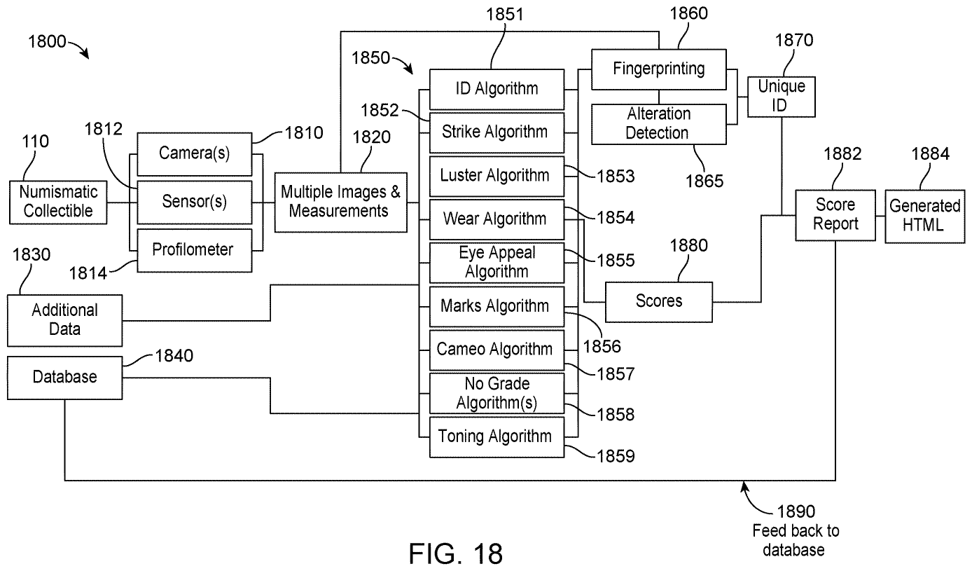

FIG. 18 schematically illustrates a computerized system 1800 for grading collectibles. The computerized system 1800 may comprise any of the components of the system 100, such as the computer system 130, for example with reference to FIG. 1. The computerized system 1800 can be configured to perform any process or algorithm as described herein.

In some embodiments, a computerized system 1800 is configured to acquire at least one image and/or measurement from a collectible 110, execute one or more processes or algorithms, and generate a grading report. In some embodiments, the algorithm is configured to one or more of identify, grade, or fingerprint the collectible 110. In some embodiments, the collectible 110 comprises one or more of a monetized coin, medal, bullion, pattern (i.e., prototype), commemorative, colonial, territorial, facsimile, counterfeit, so-called dollar, or wooden nickel, although any numismatic item can be evaluated.

The processor of the computer system 130 of the computerized system 100 referred to in FIG. 1 can be configured to control the system 1800 and perform any suitable process or algorithm as disclosed herein. In some embodiments, the processor or computer system 130 is configured to perform one or more of the processes or algorithms described herein. The computer system can be configured to process data with AI algorithms, e.g. locally deployed edge AI algorithms for example. Alternatively or in combination, the computer system can be configured to process data with a remote AI algorithms, e.g. cloud based AI algorithms for example. In some embodiments, a first portion of the data is processed with an edge AI algorithm and a second portion of the data is processed with a remote server such as a cloud based served.

In some embodiments, the processor is configured to control one or more of the camera 1810, the sensors 1812, or the profilometer 1814, for example. In some embodiments, the processor is configured to receive data from the one or more of the camera 1810, the sensors 1812, or the profilometer 1814 and generate combine data 1820. The processor can be configured to perform one or more of the processes or algorithms 1850, such as one or more of the ID process or algorithm 1851, the strike process or algorithm 1852, the luster process or algorithm 1853, the wear process or algorithm 1854, the eye appeal process or algorithm 1855, the marks process or algorithm 1856, the cameo process or algorithm 1857, the no grade process or algorithm 1858, or the toning algorithm 1859. In some embodiments, the processor of the computer system is configured with computer executable instructions to perform a plurality of these processes, for example each of these processes. Any of the one or more algorithms 1850 may comprise an edge AI algorithm, in which the algorithm is run on the system rather than remotely for example. Alternatively or in combination, the one or more algorithms may be run remotely, for example on a remote server.

The processes or algorithms 1850 can be used to evaluate any object as described herein. In some embodiments, the trained AI algorithm or process comprises one or more of an identification algorithm, a strike algorithm, a luster algorithm, a wear algorithm, an eye appeal algorithm, a marks algorithm, a visual contrast algorithm, a no grade algorithm, or a toning algorithm, for example.

In some embodiments, the ID process or algorithm 1851 is used to identify the object. In some embodiments, the ID process or algorithm 1851 is configured to identify the object in response to a 3D shape profile of the object, e.g. topography data of the object. In some embodiments, the ID process or algorithm 1851 comprises a library of 3D shape profiles of a plurality of objects and identifies the object in response to a comparison of the 3D shape profile of the object with the 3D shape profiles of objects in the library. In some embodiments, once the object has been identified, the object is compared with reference data of a corresponding object in the library of objects. This reference data of a corresponding object in the library as described herein may comprise one or more of strike data of the corresponding object, a luster data of the corresponding object, wear of the corresponding object, eye appeal of the corresponding object, a marks data of the corresponding object, a visual contrast or cameo data of the corresponding object, or toning data of the corresponding object.

In some embodiments, the strike process or algorithm 1852, is used to determine how well the object's design, e.g. 3D shape profile compares with a reference 3D shape profile, such as the 3D shape profile of a stamped object shaped with a die, a forged object shaped with compressive force, a high pressure stamping process, e.g. coin striking, embossing, impression die forming, or press forming. In some embodiments, the farther the deviation the 3D shape profile of the object is from the reference object, the lower the score.

In some embodiments, the luster process or algorithm 1853, evaluates the reflection of light from the surface of the object such as a metal object. In some embodiments, the reflection is evaluated in response to a comparison with the luster of a reference. In some embodiments, luster is created during the manufacturing process when metal is struck under high pressure by the dies. In some embodiments, this striking action causes the metal to flow outward from the center, creating microscopic parallel lines called flow lines on the object's surface. In some embodiments, when light hits these flow lines, it produces a distinctive shiny, cartwheel-like effect that appears to rotate as the object is tilted under a light source. This can be referred to as “cartwheel luster”. In some embodiments, the farther the deviation the luster of the object is from the reference object, the lower the score.

In some embodiments, the wear process or algorithm 1854, evaluates the physical loss of material and detail from the object's surface, which may be caused be related to use, such as contact and friction, for example. In some embodiments, when an object is subjected to everyday use it rubs against other which can gradually eroding the raised portions of the object. This erosion can result in a lower grade, for example. In some embodiments, the wear process or algorithm 1854 compares the measured topography of the surface of the object with the topography of the surface of a reference object. In some embodiments, the farther the deviation the 3D shape profile of the object is from the reference object, the lower the score.

In some embodiments, the eye appeal process or algorithm 1855, refers to the overall visual attractiveness of the object when viewed as a whole. In some embodiments, the eye appeal process or algorithm 1855 takes into account how all of the individual elements of an object's appearance come together, including its luster, toning, strike quality, surface preservation, and color as described herein. In some embodiments, the farther the deviation the eye appeal of the object is from the reference object, the lower the score.

In some embodiments, the marks process or algorithm 1856 evaluates imperfections on the object's surface that result from contact with other objects, machinery, or surfaces. In some embodiments, these marks are distinct from wear because they are not caused by the gradual friction related to use but rather by specific instances of impact or contact. In some embodiments, the farther the deviation the marks of the object are from the reference object, the lower the score.

The cameo process or algorithm 1857 can be used to evaluate the visual contrast of any object as described herein, for example in response to comparison with the cameo of a reference. The visual contrast between the raised design and the background, e.g. fields, can be helpful to evaluate any object as described herein. In some embodiments, cameo process or algorithm 1857 can be used to evaluate wear on parts or other components, for example. In some embodiments, the farther the deviation the visual contrast or cameo of the object is from the reference object, the lower the score.

The no grade process or algorithm 1858 can be used to evaluate any object as described herein. In some embodiments, the no grade process or algorithm 1858 can improve the accuracy of the grading, because the trained AI algorithm has the option of reporting no grade, and is not forced to complete and provide grading with other processes and algorithms and described herein. In some embodiments, no grade process or algorithm 1858 can be performed before other processes, which may also improve the efficiency of the computing process, because the computer does not need to complete the no grade process in response to a no grade determination, for example.

The toning process or algorithm 1859 can be used to evaluate the toning of any object as described herein. In some embodiments, the toning algorithm is configured to evaluate the color of the object and compare it with the color of a reference object, for example. Work in relation to the present disclosure suggests that toning is related to the natural discoloration or patina that forms on the object's surface over time. The discoloration can be related to degradation of the object such as a part. The toning may occur when the surface, e.g. a metal surface, reacts chemically with elements in its environment, such as air, moisture, and sulfur compounds found in paper holders, cloth bags, or the atmosphere. With some objects such as iron objects, the surface of the object such as a part may have a reddish rust color, for example. With some objects, e.g. silver objects, toning can appear as shades of blue, purple, gold, amber, rose, green, or even a full rainbow of colors, for example. With some objects, such as copper objects, the surface may tone in shades of brown, chocolate, and deep red, for example.

In some embodiments, the farther the deviation the toning of the object is from the reference object, the lower the score.

In some embodiments, the processor is configured to perform one or more of the fingerprinting process 1860, the alteration detection process 1865 or the scores process 1880.

In some embodiments, the processor is configured to perform one or more of the score report process 1882 or the generated HTML 1884, for example. In some embodiments, the report is printed. The report or reports can be made available in other formats known in the art such as PDF, word processing document, or a CSV.

In some embodiments, the processor is configured to provide feedback 1890 to the database 1840. The database 1840 may comprise a remote database, such as a database on a remote server such as Amazon Web Services (AWS). Alternatively or in combination, the database 1840 may comprises a local database, for example located on the computer system 130 with reference to FIG. 1.

In some embodiments, the combination of a profilometer 1814 with one or more cameras 1810 and sensors 1812 is utilized to collect measurements or images from the collectible 110. The profilometer 1814 may comprise any suitable profilometer to acquire profile data of the collectible, such as 3D surface profile data of the collectible. The profilometer 1814 may comprise a contact or non-contact profilometer. The profilometer may comprise one or more of a structure light illumination system, a laser confocal scanning system, a white light interferometry system, a focus variation system, or elastomeric sensor technology system. The structure light illumination system may comprise a structured light illumination system commercially available from Keyence (Keyence.com), for example. The laser confocal scanning system may comprise a laser confocal scanning system commercially available from Keyence, for example. The focus variation system may comprise a focus variation system commercially available from Keyence, for example. The elastomeric sensor system may comprise an elastomeric sensor system commercially available from GelSight (Gelsight.com), for example.

The camera 1810 may comprise any device configured to capture at least one instance of light in the form of images, such as images formed with an imaging lens. The camera 1810 may operate across one or more parts of the electromagnetic spectrum (e.g., visible, infrared, or ultraviolet), may operate on the basis of any sensor (e.g., CMOS or CCD) and may utilize any suitable lens technology (e.g., single-lens reflex, mirrorless, bridge, etc.). In some embodiments, data from a camera 1810 can be used alone such as for the evaluation of the toning (FIG. 14) by the toning algorithm 1859 or eye appeal algorithm 1855; or can be combined with other collected data or information to perform analyses such as identifying a foreign object stuck to the surface of the collectible. Other sensors 1812 can be used collect additional data that may not be captured by the profilometer or cameras and may rely measurement under different conditions or at a higher resolution. In some embodiments, the sensors 1812 are related to the luster analysis equipment described in FIG. 10. In some embodiments, additional information or data 1830 is input into the system.

In some embodiments, the sensors 1812 are related to analyzing the surface chemistry of the collectible or other substances that are on or may have been added to the surface, potentially unscrupulously (e.g., “putty”). In some embodiments, the sensors 1812 are related to analyzing the bulk or location specific chemistry of the numismatic collectible such as by XRF or laser-based elemental analysis, or energy-dispersive X-ray spectroscopy (EDS). In some embodiments, the sensors 1812 are related to the collection of toning data in addition to the data from the camera 1810, such as hyperspectral imaging or a color meter combined with a 3D profilometer such as the commercially available system from BYK Instruments (byk-instruments.com), for example. In some embodiments, the sensors 1812 are related to the collection of data at additional wavelengths within or outside the visible spectrum such as the commercially available hyperspectral imaging system from Konica Minolta (konicaminolta.us), for example. Although the example sensor types are referenced individually, in some embodiments, the sensors available to collect data may comprise two or more, three or more four or more, or five or more of the forgoing.

The additional data 1830 may comprises any suitable data, such as one or more of specification, numismatic details, catalog information, or attribution, for example. In some embodiments, this data may be read by a computer of the system, e.g. a processor. The database 1840 may comprise data from prior measurements of numismatic collectibles. In some embodiments, the database 1840 comprises data from each of a plurality of previously graded collectibles.

In some embodiments, data from at least one profilometry measurement is combined with data from another device, such as sensors 1812 or camera 1810 to generate combined data 1820.

In some embodiments, one or more different illumination conditions may be used between a plurality of images with one or more camera 1810, one or more sensors 1812, or one or more profilometers 1814. In some embodiments, this is a requirement of the individual components of the image acquisition device 120 or performed to capture multiple instances or views of the numismatic collectible 110.

In some embodiments, the combined data 1820 comprises additional information or data 1830. While the combined data 1820 can be generated in many ways, in some embodiments, the profilometry data, e.g. 3D topography data from the profilometer 1814 is registered with other types of data such as color data and reflectance data from the camera 1810 or data from the one or more sensors 1812. In some embodiments, the pixel or voxel data from the 3D profilometer is registered with color data such as RGB data from a camera or vice versa. This registration may comprise one or more of rotation or translation of the camera data with the profilometer data to align the two data sets. Alternatively or in combination, this registration may comprise one or more of rotation or translation of the profilometer data with the camera data to align the two data sets. In some embodiments, for each point of a plurality of points in the profilometry data set, corresponding data from the camera image is associated with the plurality of points. Additional data such as reflectance data can be registered and associated with the plurality of points of the profilometry data set. This registration and alignment can involve at least 1000 points, 10,000 points, 100,000 points, or at least 1,000,000 points, in accordance with some embodiments.

In some embodiments, the combined data 1820 are provided to at least one process or algorithm 1850 that one or more of identifies the collectible (ID algorithm) 1851, assesses at least one aspect of the collectible's quality (e.g. strike algorithm 1852 or cameo algorithm 1857) (FIG. 4 & FIG. 13) or assess the state of preservation (e.g., marks algorithm 1856 or wear algorithm 1854) (FIG. 15 & FIG. 5). In some embodiments, the individual algorithms 1850 map the features to an overall coin grade.

In some embodiments, the coin grade is consistent, repeatable, and accurate, in some instances beyond the capabilities of human graders.

In some embodiments, the toning algorithm 1859 can receive the distribution of colors present and their spatial relationship to determine whether the toning pattern is questionable in relation to an intent to deceive a ranking of the attractiveness of the toning pattern. In some embodiments, the toning algorithm 1859 comprises a machine learning model. In some embodiments, the machine learning model used to evaluate the questionable nature and attractiveness of the toning pattern. In some embodiments, the toning algorithm 1859 comprises one or more of a convolutional neural network, or a deep learning model that learns hierarchical patterns from pixel data. In some embodiments, the toning algorithm 1859 comprises a model type or architecture such as transformers, which may use self-attention for global context, for example. In some embodiments, mathematical manipulations and machine learning models can be used for each of the processor or algorithms 1850, fingerprinting process 1860, detecting alterations, and compilation of scores into a singular grade, for example.

For each of the processes or algorithms, additional information or data 1830, including that from the database 1840 of previously graded collectibles, can be made available by human or computerized input. The individual processes or algorithms 1850 may operate on the same or partially the same subsets of data collected from the collectible. Some algorithms may utilize all or parts of the finished analyses from other algorithms to decrease, e.g. minimize, repeated processing and accelerate evaluation. For example, the eye appeal algorithm 1855 can use results from the luster algorithm 1853, cameo algorithm 1857, and toning algorithm 1859.

In some embodiments a finger printing process 1860 configured to create a unique fingerprint of the collectible 110 (see, e.g. 1605 of FIG. 16) of the collectible. In some embodiments, the initially collected image and measurements data 1820 are input into the fingerprinting process 1860. Alternatively or in combination, the outputs of one or more of the processes or algorithms 1850 can be input into the fingerprinting process 1860. For example a plurality of outputs of the one or more processes or algorithms can be input into the fingerprinting process 1860. In some embodiments, each of a plurality of the processes or algorithms 1850 are input to the fingerprinting process 1860.

In some embodiments, the unique fingerprinting process 1860 is configured such that the collectible 110 would be recognizable, e.g. identified, if resubmitted without any changes or alterations.

In some embodiments, alteration detection process 1865 is performed by an algorithm that evaluates the similarity of aspects of the collectible 110 currently being graded to other examples seen previously and stored in the database 1840. In some embodiments, this can be performed by evaluating the similarity to the overall (e.g., including toning, marks, luster, etc.) fingerprint's 1860 mathematical representation of the collectible 110 to other collectibles previously seen or for the individual components of the fingerprint. In some embodiments, being able to perform the alteration detection 1865 analysis at the individual component (e.g., marks) level makes it possible to identify when one or more components of the numismatic collectible 110 (e.g., the toning) has intentionally been altered to deceive the grading process. In some embodiments, this may allow identification of other forms of alteration such as artificially toning several coins 110 with the same pattern which will have a high toning similarity.

In some embodiments, the combination of the data collected from the numismatic collectible 110, the results, e.g. output, from the algorithms 1850, the fingerprinting 1860, the alteration review 1865, and the scores 1880 are linked to a unique ID 1870 for that collectible 110. In some embodiments, the unique ID is a unique identification code that uniquely identifies the collectible among a plurality of collectibles and identification codes.

In some embodiments, these output data from one or more of the algorithms 1850, the finger printing process 1860, scores 1880, the alteration detection 1865 or the unique ID 1870 are compiled into a score or grade report 1882. In some embodiments, this output data is provided to the database 1840 with feedback 1890, and stored in the Database 1840. In some embodiments, the data output into the grade report 1882 are user selectable to customize the report. In some embodiments, selections are made available as part of a grade report (see grade report 300 with reference to FIG. 3, for example). In some embodiments, the report is generated as an HTML file 1884, for example, although other formats may be used.

In some embodiments, the database 1840 comprises a datastore of known collectibles 110, such as but not limited to coins. The database 1840 comprises as much data of collectibles 110 as possible, and grows as additional collectibles 110 are evaluated or information is otherwise added. Along with measurements 1820 from the collectible 110, a set of metadata is stored, which can comprise information about the collectible or coin 110, such as but not limited to: manufacturer of the coin; year of the coin's manufacturing; internal specification number; any variety particular to that coin (e.g., Cheerios Dollar or 1803 Draped Bust Cent Sheldon 249 variety); or any historical provenance information.

In some embodiments, the grading report 1882 is linked to a certification number 340 and made available to the submitter and other individuals, such as people in the industry who search for the collectible 110 online or in an app by its certification number by typing the number into a database, scanning a query response (QR) code, interacting with an in-slab data transmitter (e.g., RFID tag) or other identification. In some embodiments, the information and metadata about each collectible 110 graded is also stored in one or more databases 1840 for various purposes including ranking the graded collectible 110 against all others graded, identifying 1851 a coin 110 going through the grading process, developing a registry, performing statistical analysis on components of the grading and score reports 1182, etc.

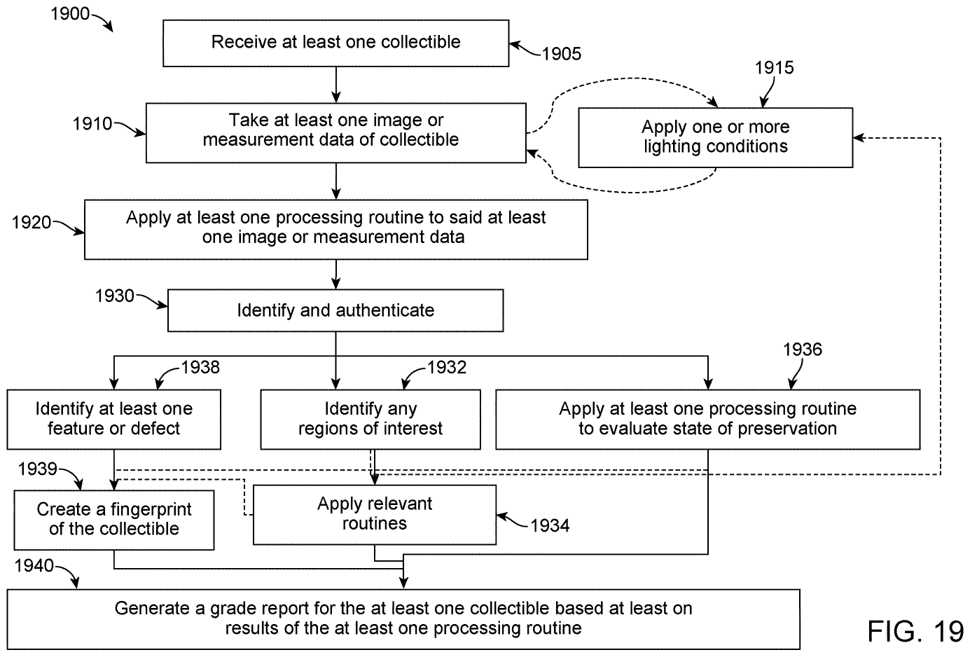

FIG. 19 shows a flowchart of a method 1900 of grading a collectible 110.

At a step 1905, at least one collectible is received. The collectible may be placed on the stage as described herein, for example. Upon completion of the process, the collectible can be removed and another collectible evaluated. Alternatively or in combination, the stage may comprise a motorized stage to evaluate a plurality of collectibles, for example a plurality of collectibles on a tray.

At a step 1910, at least one image or measurement is taken from the collectible 110. The collectible 110 might be a monetized coin, medal, bullion, pattern (i.e., prototype or test piece), commemorative, colonial, territorial, or other numismatic item.

At a step 1915, one or more lighting conditions may be changed between subsequent images or measurements 1910.

At a step 1920, at least one processing routine may be applied in response to the grading apparatus receiving the at least one image or measurement 1910 of the collectible 110.

At a step 1930, identification and authentication of the collectible 110 is performed. This step may be performed using a combination of the measurement or image data 1820 from the collectible, reference information or data 1830, information from the database 1840, and/or external input (e.g., human aided identification in the case of a newly seen collectible type).

At a step 1938, at least one feature or defect is identified.

At a step 1932, regions of interest are identified. In some embodiments, determination of the collectible's identity may trigger regions of interest to be further investigated.

At a step 1936, at least one processing routine is applied to evaluate a state of preservation of the collectible.

At a step 1939, a fingerprint of the collectible is created.

At a step 1934 relevant routines are applied.

At a step 1940, a grade report is generated.

In some embodiments, at step 1934 collectible-type specific processing routines are applied in response to the state of preservation performed at step 1936. For example, the specific collectible-type specific processing routines may comprise a full head strike designation assessment for a standing liberty quarter. As another example, a collectible identified as a capped bust half dollar may trigger the specific collectible-type specific processing routines for determination of the Overton variety number. Alternatively or in combination additional imaging or data collection as indicated at step 1910 can be performed, for example under the same or different lighting conditions can be performed, for example as indicated at step 1915, in response to the specific type of collectible. In some embodiments, the at least one image or measurement data may be acquired at a different resolution and/or magnification, in response to the specific type of collectible, for example.

In some embodiments, at step 1936 the state of preservation comprises an evaluation of at least one aspect of the grading the numismatic collectible, such as one or more of strike, marks, luster, wear, or eye appeal.

In some embodiments, at least one of the features or defects identified at step 1938 is optionally combined with at least one piece of information from the identity, authentication 1930, or state of preservation evaluation 1936 to create a fingerprint of the collectible 110 at step 1939.

In some embodiments, one or more of the images, measurements, or outputs of the at least one processing routine are combined at step 1940 to generate a grade report for the collectible as described herein.

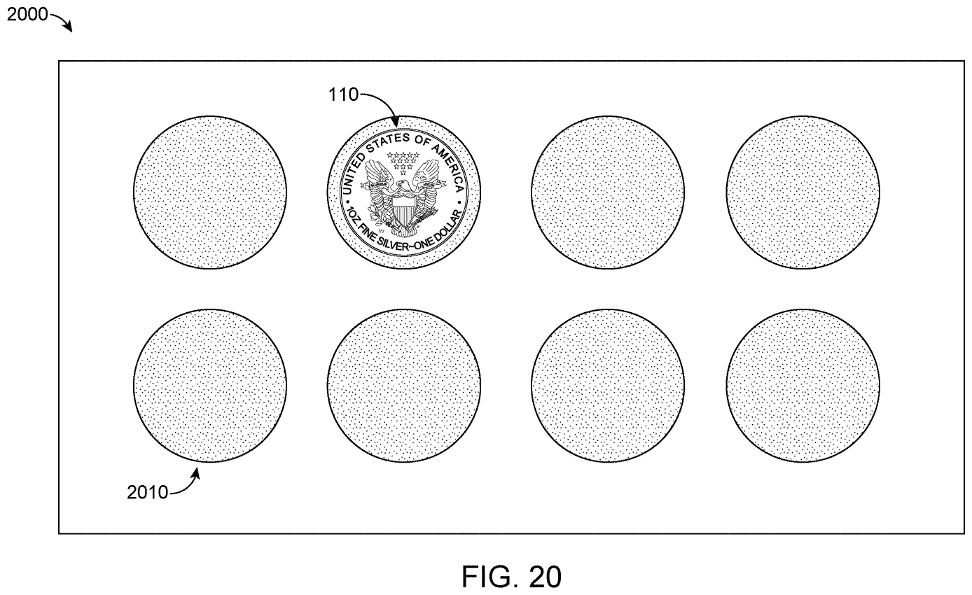

FIG. 20 is a diagram illustrating an example of a loading tray 2000 for presenting one or more collectibles 110 such as coins to computerized system. The optional use of a loading tray 2000 creates unique locations 2010 for the computerized systems to locate one or more collectibles 110 for evaluation 1905. In some embodiments, the computerized system is configured to operate in a batch mode such that the one or more collectibles 110 received by the system are individually evaluated once the loading tray 2000 is in place or triggered manually.

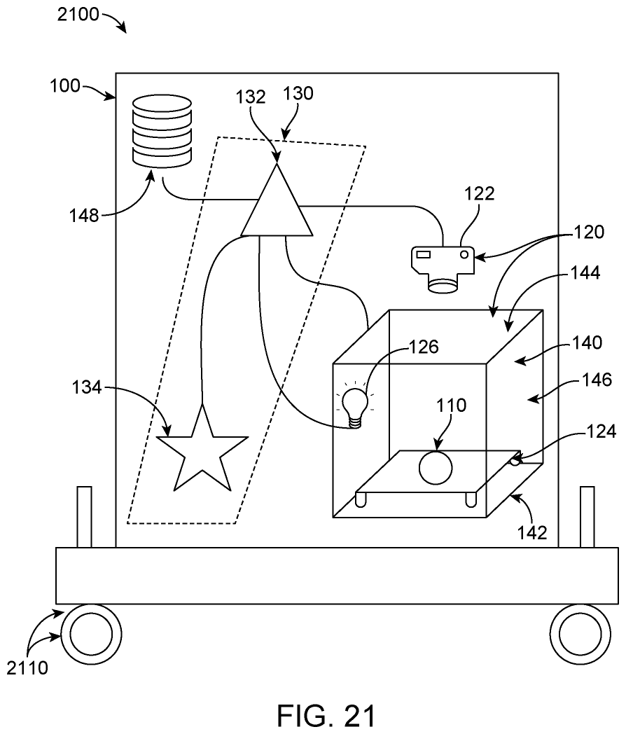

FIG. 21 is a diagram of a remote grading unit 2100. The remote grading unit may comprise any of the features of computerized system 100 as described herein. In some embodiments, the unit may also comprise a mobile remote grading unit by the addition of wheels, a flatbed, trailer, or other means of making the unit mobile 2110. In some embodiments, the remote grading unit allows for the computerized grading and authentication disclosed herein to be accomplished, at least partially, at such a numismatic expo, numismatic shop, or similar event or location. In some embodiments, the remote grading unit 2100 can be configured with to allow for the legal owner or submitter of the collectible 110 to remain within the vicinity of the collectible while it is being graded. In some embodiments, the remote grading unit 2100 can be set up at other independently operated locations (e.g., an independent coin shop) and provide at least a partial grade report (with or without a holder or slab 2200, see FIG. 22) up to a complete grade report (also with or without a holder or slab). In some embodiments, the remote grading unit is capable of carrying out one or more of the following functions: acquiring images and measurements of the numismatic collectible, identifying and verifying the collectible, producing at least a partial grading report, or physically encasing 2200 the graded collectible. In this manner, buyers and sellers can make more informed opinions about the value of a collectible without requiring it be mailed or brought to the third-party grading service or their presence at a numismatic event.

FIG. 22 is a diagram illustrating an example of a protective slab 2200. Protective slabs contain the coin 110 and at least one of the pieces of information derived from or related to the identification, authentication, grade, processing routines, designations, reason(s) for “No Grade”, or sub-grades of the collectible as described herein. In some embodiments, the right side of the diagram shows an example of the information presented within or on the slab 2210. In some embodiments, slabs 2200 may comprise a plurality of layers to provide at least one of collectible protection, tamper resistance, counterfeit deterrence, security devices, information about the collectible, the certification number 340. The methods, systems and apparatus of the present disclosure are well suited for measuring collectibles 110 contained within such slabs 2200, in accordance with some embodiments of the present disclosure.

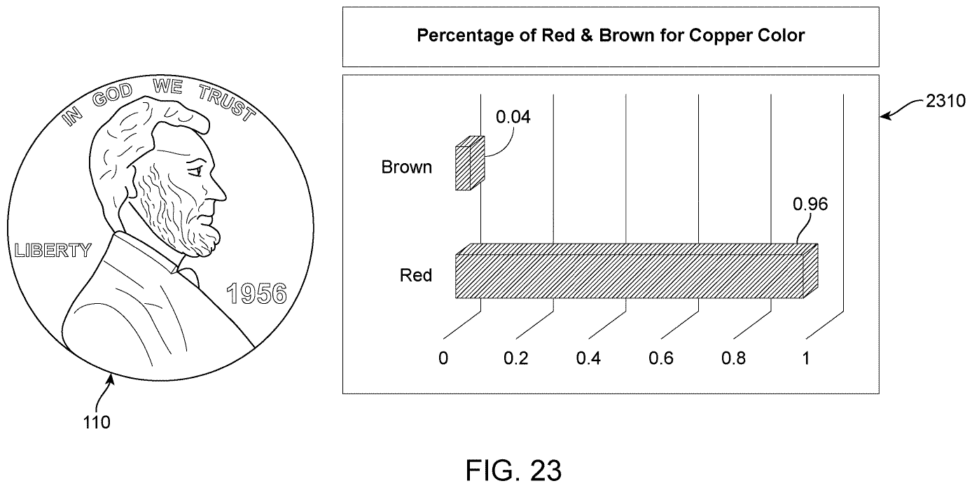

FIG. 23 shows a view of the obverse a collectible, and a view of the copper color scores of the grade report from the computerized systems, in accordance with some embodiments. In some embodiments, the score report for the copper color designation is performed by the computerized grading system as described herein. In some embodiments, the percentage of the copper collectible 110 that is “mint red” (also simply “red”) or “brown” is determined from at least one image or other measurement of the collectible 110. In some embodiments, depending on the amount of red remaining on the coin, the copper color designation of red, red and brown, brown and red, or brown (in decreasing order of the amount of red remaining) is assigned. In some embodiments, the percentage of red or brown 2310 may be reported in addition to or in lieu of the qualitative (e.g., red and brown) descriptor.

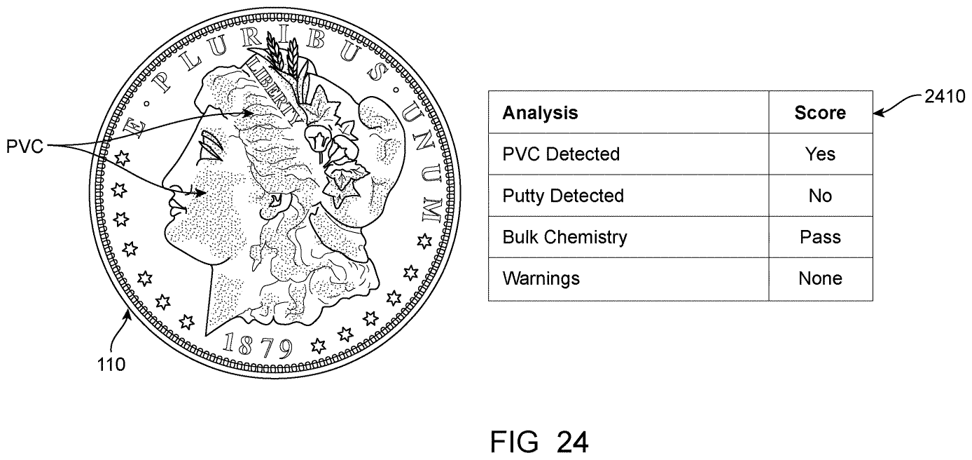

FIG. 24 provides an example of the surface, trace, and bulk chemistry measurement output 2410 that may be performed and provided by the grading apparatus as part of authentication and grading of the collectible 110. In some embodiments, the bulk chemistry, including trace elements, is relevant to determine the authenticity of the collectible (e.g., trace iridium and iron content in Russian platinum coins). In some embodiments, surface chemistry can be used to identify mis-handling (e.g., environmental damage or PVC) and intentional alterations (e.g., addition of a material generally referred to as “putty” to the surface to hide defects or damage).

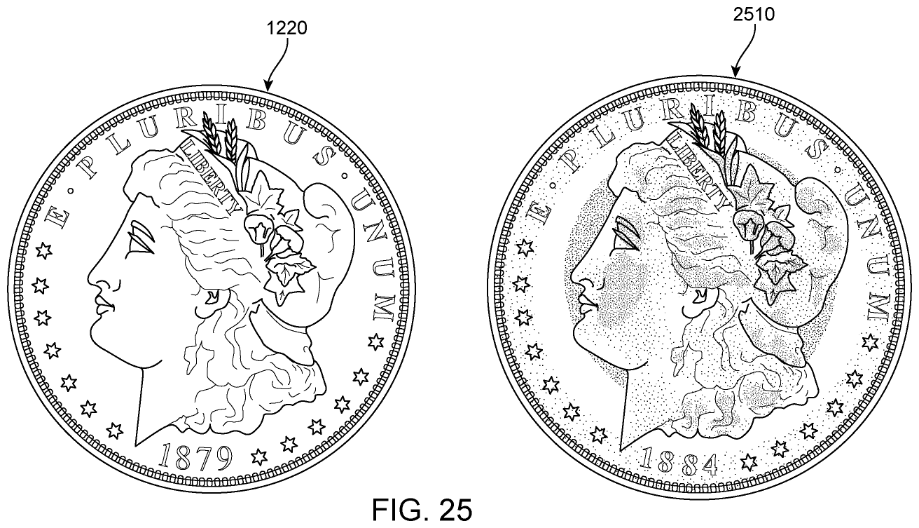

FIG. 25 shows a view of a golden image 1220 of collectible 110 and the relief 2510 of the golden image, in accordance with some embodiments. In some embodiments, the golden image 1220 comprises an ideal image without any unintended defects. In some embodiments, the golden image comprises image data, such as 3D image data. The data of the golden image may comprise 3D topography data or other data as described herein, for example. In some embodiments the golden image 1220 may be one or more of supplied by the creator, made from measurements of the dies, dies or other tools used for its fabrication, created by altering or enhancing the measurements from a collectible, made by removing all detectable defects unintended by its originator, the highest quality collectible of that type, or by assembling pieces of measurements of other collectibles of the type or some combination of these methods. In some embodiments, the computer aided design and/or image processing to create the golden image 1220, e.g. the image data such as 3D image data, may be performed manually and/or with the use of machine learning, and combinations thereof, for example.

In some embodiments, the digital twin of the collectible under test comprises data related to reference data such as golden image data. In some embodiments, the digital twin data comprises any of the data used to evaluate the collectible. In some embodiments, the digital twin data comprises data of one or more of 3D shape profile data, ID data, strike data, luster data, wear data, eye appeal data, marks data, cameo data, no grade data or toning data. Although reference is made to one or more, the digital twin data may comprise two or more, three or more four or more, or five or more of the forgoing.

The data of the golden image 1220 may comprise any of the data used to evaluate the collectible. In some embodiments, the golden image data comprises data of one or more of 3D shape profile data, ID data, strike data, luster data, wear data, eye appeal data, marks data, cameo data, no grade data or toning data. Although reference is made to one or more, the golden image data may comprise two or more, three or more four or more, or five or more of the forgoing. These data can be used for comparison with the collectible being evaluated and correspond with data from one or more of the multiple images and measurements 1820, ID process or algorithm 1851, strike process or algorithm 1852, luster process or algorithm 1853, wear process or algorithm 1854, eye appeal process or algorithm 1855, marks process or algorithm 1856, cameo process or algorithm 1857, no grade process or algorithm 1858, or toning process or algorithm 1859, for example with reference to FIG. 18. Although reference is made to one or more, the one or more algorithms 1850 may comprise two or more, three or more four or more, or five or more of the forgoing. In other words, each of these algorithms may have golden image data associated with it that is compared with the data from the collectible as part of the process that executes the algorithm. Although reference is made to one or more types of golden image data, the golden image data may comprise two or more, three or more four or more, or five or more of the forgoing.

In some embodiments, the golden image data comprises golden digital twin data of one or more of 3D shape profile data, ID data, strike data, luster data, wear data, eye appeal data, marks data, cameo data, no grade data or toning data. Although reference is made to one or more, the golden digital twin data may comprise two or more, three or more four or more, or five or more of the forgoing.

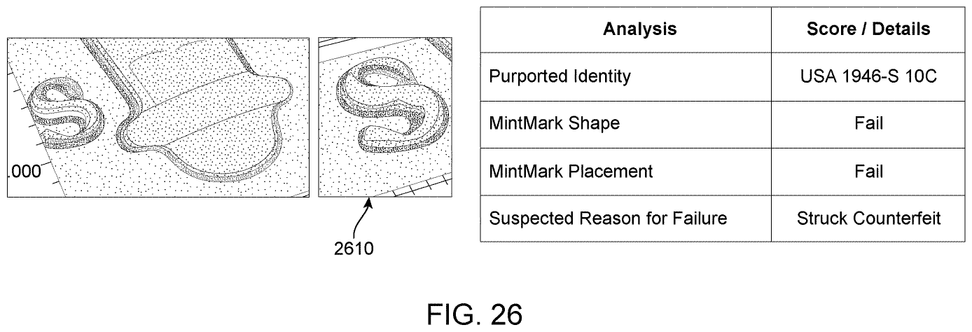

FIG. 26 provides an example of score reports and analysis of data related to the identification and authentication process used by the grading system disclosed herein. Details of a particular collectible 110 (e.g., the date, mintmark 2610, die markers, etc.) have known placement(s), shape(s), or other aspects of them on genuine examples. Attempts to alter or counterfeit a collectible 110 are detected by the presence or absence of these certain features. Additional features, such as tooling marks or evidence of solder from an attempt to modify or add a feature such as a mintmark or Full Head, can also be used to detect these counterfeits and alterations. In some embodiments, the grading apparatus not only detects such an attempt, but provides the detected reason for failure at least for internal use of the grading company. It may also be part of the grading report as described herein.

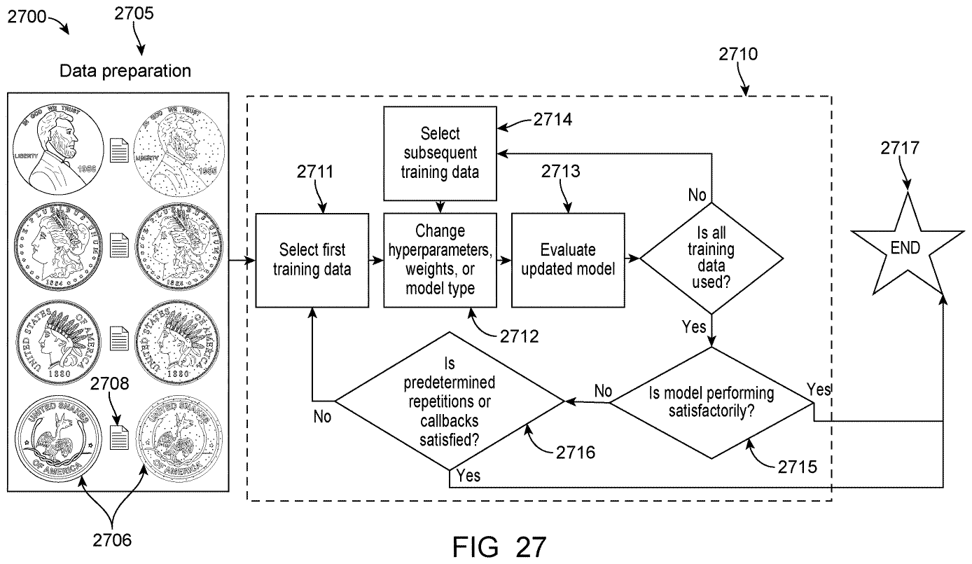

FIG. 27 shows a method 2700 of training an AI algorithm. In some embodiments, the AI model(s) for collectible evaluation are trained through a systematic process. The AI algorithm can be trained to perform each of the processes or algorithms of the system 100 as described herein, for example with reference to the processes and algorithms of FIGS. 18 and 19.

In some embodiments, at a step 2705 of data are prepared and preprocessed. In some embodiments, data 2706 from one or more raw images or measurements and the associated metadata 2708 of collectibles are gathered and standardized into consistent formats and resolutions. In some embodiments, data cleaning removes corrupted files, duplicates, and outliers to ensure dataset quality, while labeling of individual inputs involves annotating the data of each collectible's 110 specific characteristics such as condition defects, authenticity markers, strike quality, luster quality, eye appeal, and other physical attributes (Refer to FIG. 18 and Table 1) that are desired features for a given model to learn to map to a component of a coin's grade (e.g., eye appeal) or the overall grade of the collectible 110. In some embodiments, labeling the ground truth grade establishes the target by assigning verified condition grades based on established grading standards or expert assessments for each of a plurality of collectibles in the training data set. In some embodiments, the data are unlabeled and unsupervised model(s) independently learn to correlate specific characteristics such as condition defects, authenticity markers, strike quality, luster quality, eye appeal, and other physical attributes (Refer to FIG. 18 and Table 1)) that are desired features for a given model to learn to map to a component of a coin's grade or the overall grade of the collectible 110.

At a step 2710, the model is trained. In some embodiments, training the model involves feeding the prepared dataset through machine learning algorithms that learn to correlate visual, measurement, and metadata features with the ground truth grades, or at least one aspect or component of the ground truth grade, through iterative optimization. In some embodiments, the iterative optimization process can include splitting the dataset into batches at step 2711, and testing several different models (e.g., random forest, k-nearest neighbors, or neural networks). In some embodiments, at a step 2712 parameters are modified, including modifying the hyperparameters (e.g., number of decision trees or neuron activation function), and the coefficients of the model (e.g., weights in a neural network). At a step 2713, the updated model is evaluated. In some embodiments, validating the model tests performance on unseen data to measure accuracy and prevent overfitting, using metrics like precision, recall, and grade prediction accuracy. In some embodiments at a step 2714, if unused training data remains, subsequent batches of data are delivered to the model optimization routine and parameters modified at step 2712. In some embodiments, once all available training data has been evaluated at least once, the performance of the model is evaluated at step 2715, typically using the data set aside for validation but other metrics can be monitored. In some embodiments, if the model is not performing satisfactorily, further pass(es) through the entire training data, referred to as an epoch, can be performed at step 2716. In some embodiments, because a single pass through the training data is usually insufficient, models are generally trained over multiple epochs to improve accuracy. In some embodiments, the model is deployed at step 2717. In some embodiments, deployment and monitoring involves implementing the trained model in production environments while continuously tracking its performance, retraining as needed, and updating the system based on new data and changing market conditions to maintain grading accuracy and reliability.

Referring again to FIG. 18, in some embodiments, the image and data analysis processor or algorithms 1850 employ a comprehensive suite of artificial intelligence algorithms to process and analyze digital image data with enhanced accuracy and efficiency. In some embodiments, the system utilizes at least one algorithmic approach for image analysis on at least one subset of the data collected from a collectible 110 being graded. The types of algorithms that accomplish the image analysis include but are not limited to deep learning architectures such as Convolutional Neural Networks (CNNs) for spatial feature extraction and pattern recognition, which may include LeNet architectures with alternating convolutional and pooling layers, AlexNet architectures featuring multiple convolutional layers with ReLU activation functions and dropout regularization, VGG networks utilizing small 3×3 convolutional filters applied consistently throughout the network, ResNet architectures that address the degradation problem through skip connections enabling training of very deep networks, Inception networks that capture features at multiple scales through parallel convolutions of different sizes, and DenseNet architectures where each layer connects to every other layer in a feed-forward fashion to promote feature reuse. The system can optionally incorporate Recurrent Neural Network (RNN) modules for handling sequential and temporal aspects of image data, Additionally, the individual models or system can optionally implement Transformer modules with attention-based architectures for capturing long-range dependencies and global context, including Vision Transformer (ViT) architectures that divide images into patches and process them as sequences using transformer encoders, Swin Transformers that compute self-attention within local windows and gradually merge windows for multi-scale feature capture, and multi-head attention mechanisms that allow joint attention to information from different representation subspaces.

In some embodiments, the system also optionally utilizes Generative Adversarial Network (GAN) modules for image generation, enhancement, and analysis, comprising generator networks that learn to generate realistic images of numismatic collectibles 110 or selected aspects of them (e.g., toning patterns 1430 in accordance with FIG. 14) from random noise or latent representations, discriminator networks that distinguish between real and generated images, and conditional GANs that generate images based on additional information such as class labels.

Traditional machine learning algorithms may also be employed including Support Vector Machine (SVM), Random Forest, K-Means clustering algorithms, Principal Component Analysis (PCA), etc.

The disclosed coin grading system may employ hybrid algorithmic approaches that combine multiple types of artificial intelligence models, such as CNN-RNN hybrid architectures for spatial feature extraction followed by temporal modeling, CNN-Transformer hybrid models that combine spatial feature extraction with global context modeling, and ensemble methods that combine predictions from multiple algorithms for improved performance and robustness. The algorithms that enable evaluation of the different components of grading 1850 a coin 110 (refer to FIG. 18) may utilize unique artificial intelligence modeling approaches with distinct or overlapping sets of input information.

In some embodiments, a coordination engine serves as the central control system that analyzes incoming image data to determine characteristics such as image type, resolution, complexity, and domain, implements algorithm selection logic through decision trees or learned models, manages computational resources to meet performance constraints, and continuously optimizes performance through monitoring and learning from analysis results. In some embodiments, the processing pipeline includes preprocessing stages for image normalization, resizing, and augmentation, feature extraction using selected algorithms, feature fusion through concatenation, weighted averaging, or learned fusion networks, classification or analysis of fused features, and post-processing refinement through techniques such as non-maximum suppression, confidence thresholding, or ensemble voting, thereby providing a comprehensive and adaptive framework for numismatic image or other data analysis applications.

In accordance with some embodiments, the exemplary computer-aided and computer-driven techniques for grading a collectible are provided in FIG. 18 and the associated description.

In some embodiments, the ID algorithm 1851 uses one or more of topography data or topology data, image data, or some combination thereof to identify and authenticate the collectible 110. FIG. 26 shows a view of the data and report, in accordance with some embodiments. Example AI model architectures for accomplishing this task are image classification models (e.g., convolutional neural networks or transformers), optical character recognition, or topology & point cloud models (e.g., geometric deep learning and point cloud models such as PointNet, PointCNN, or Point Transformer). In some embodiments, the AI algorithm is trained to identify information about the collectible 110, such as but not limited to: manufacturer of the coin; year of the coin's manufacturing; any variety particular to that coin (e.g., Cheerios Dollar or overdate).

In some embodiments, the strike algorithm 1852 uses one or more of topography data or topology data to determine the height of one or more points on the collectible compared to a reference zero height such as a point in the field or an average height of all or a portion of the fields, or another location or region. In some embodiments, this information is further combined with a golden image 1220 or reference heights to assess the degree of relief imparted to the collectible 110 being graded compared to a standard, a population, or table of degrees of strike (FIG. 11). In some embodiments, the height measurements are also used for determining the method of manufacture (i.e., business or proof strike). In some embodiments, the strike algorithm 1852 is also used to evaluate the striking characteristics of specific regions of the collectible such as for Full Bands on a Mercury Dime or Full Head on a Standing Liberty Quarter (FIG. 4).

In some embodiments, the luster algorithm 1853 is trained to evaluate the measurements related to luster, for example as described with reference to FIG. 10, and to identify the luster type 1010, luster quality for the type 1020, and if the coin is proof like; deep mirror proof like; or proof; then it also assesses the depth of the mirrored surfaces 1030 and the contrast between the fields and the devices 1040. In some embodiments, this is accomplished using a machine learning model, such as k-nearest neighbors (although others may be used) to determine where each component of luster ranks with respect to the population for any of the following: the entire universe of collectibles 110, the specific series of collectible (e.g., Morgan Dollars), the date and series (e.g., 1883 Morgan Dollars), the mintmark and series (e.g., Carson City Morgan Dollars), or the date, mintmark, and series (e.g., 1883 Carson City Morgan Dollars).

In some embodiments, the wear algorithm 1854 is trained to evaluate the degree of detail loss or conversely the amount of remaining detail on the collectible (FIG. 5). In some embodiments, the AI model utilizes one or more the topography data or the topology data with or without a golden image 1220 to score the amount of detail remaining on the front and back of the collectible. In some embodiments, the trained topography or topology AI model operates independently to discriminate where the loss of detail for the collectible being graded would place the coin compared to what it has learned in the data from the training set. In some embodiments, this is performed by assessing the loss of detail in one or more specific regions, for example, the wing feathers on the eagle of a USA twenty cent piece.

In some embodiments, the eye appeal algorithm 1855 is trained to rate the overall eye appeal of a collectible 110 and thus determine how many points should be added (positive eye appeal) or subtracted (negative eye appeal) from the overall grade. In some embodiments, the scores for toning, luster, and other components of a collectible's “eye appeal” can be determined independently by this AI model or use the scores from the individual component models such as the toning algorithm as inputs.

In some embodiments, the marks algorithm 1856 is trained to identify, classify, and score the impact of the variety of contact marks, dings, scuffs, counting marks, machine damage, and other forms of mechanical damage a collectible 110 may exhibit. In some embodiments, the algorithm learns the importance of the type of mark, its size and severity (FIG. 15), and the placement of the mark on the coin 110. In some embodiments, the importance of each mark is assessed individually or with all other marks to create a marks score report as one component of the collectible's grade. In some embodiments, the algorithm is trained with explicit knowledge of how the coin 110 is subdivided into regions of high impact (e.g., a primary focal point on the coin) or low impact (e.g., hidden in the hair detail) 2800.

In some embodiments, the cameo algorithm 1857 assesses the degree of contrast between at least one region of the fields 1050 and devices 1060, for example the contrast between all of the field and devices (FIG. 13). In some embodiments, the collection of contrast measurements are mathematically correlated to a cameo score. For example, a collectible 110 exhibiting medium contrast on average between the fields and devices would correlate with being called Cameo. In another embodiment, the collection of contrast measurements are fed into a trained machine learning model to score the cameo contrast as described herein.

In some embodiments, the no grade algorithm(s) 1858 comprises one or more models trained to detect the variety of damage, alterations, counterfeiting, chemical substances, etc. that result in a coin 110 being ineligible for a precise grade (refer to Table 1). In some embodiments, depending on the severity and type of the issue, the collectible 110 may be assigned a qualitative adjective (e.g., very fine details), identified only as genuine, denoted as authenticity unverifiable, or labeled as a counterfeit. As an example, in some embodiments the no grade algorithm(s) 1858 includes an artificial toning detector that has been trained to discriminate toning that appears to be legitimate from suspect toning or toning that is known to be produced via human intervention. In some embodiments, the flagging of suspect toning in the toning algorithm 1859 is passed to this No Grades discriminator algorithm 1858 as an input.

In some embodiments, the toning algorithm 1859 utilizes one or more AI models to assess at least the attractiveness of any toning present on a collectible 110. In some embodiments, a vision AI model such as a CNN learns to correlate the spatial pattern and colors of toning with its attractiveness in the marketplace. In other embodiments, the distribution of the colors present in the pixels without their spatial component is used to accomplish this. In some other embodiments, the assessment of both models is used to quantify the toning score. In any of these embodiments, the toning algorithms 1859 can also be used to flag or identify toning patterns that are suggestive of an intent to deceive (i.e., artificial toning), for example.

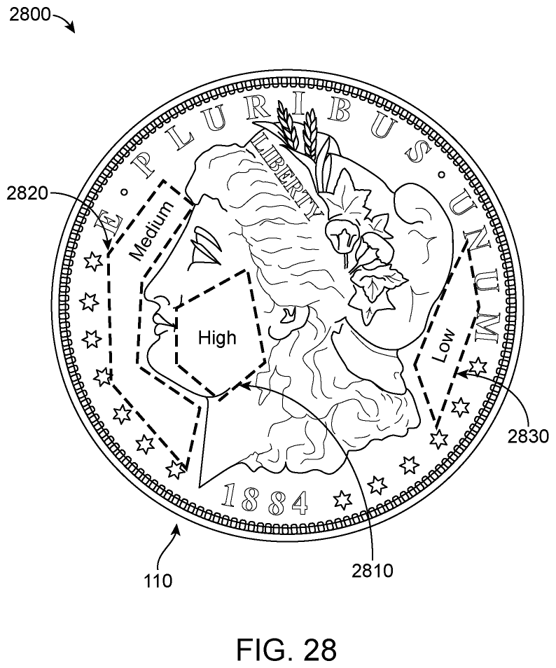

FIG. 28 provides an example of a coin 110 subdivided into regions of higher impact (e.g., a primary focal point on the coin) 2810, medium impact 2820, or lower impact (e.g., the area behind the portrait on a coin) 2830. In some embodiments, the entire collectible will be subdivided into regions of varying importance, in a manner such as a heatmap or other methods known to someone skilled in the art. When grading a coin, some positive or negative aspects of a coin's grade may have a greater impact on the coin's grade when located in a high impact region and vice versa. For example, a large contact mark in a prime focal area, such as the cheek of a Morgan Dollar numismatic collectible 110, will be more significant than if the same exact contact mark were placed behind her head or hidden in the hair detail, in accordance with some embodiments.

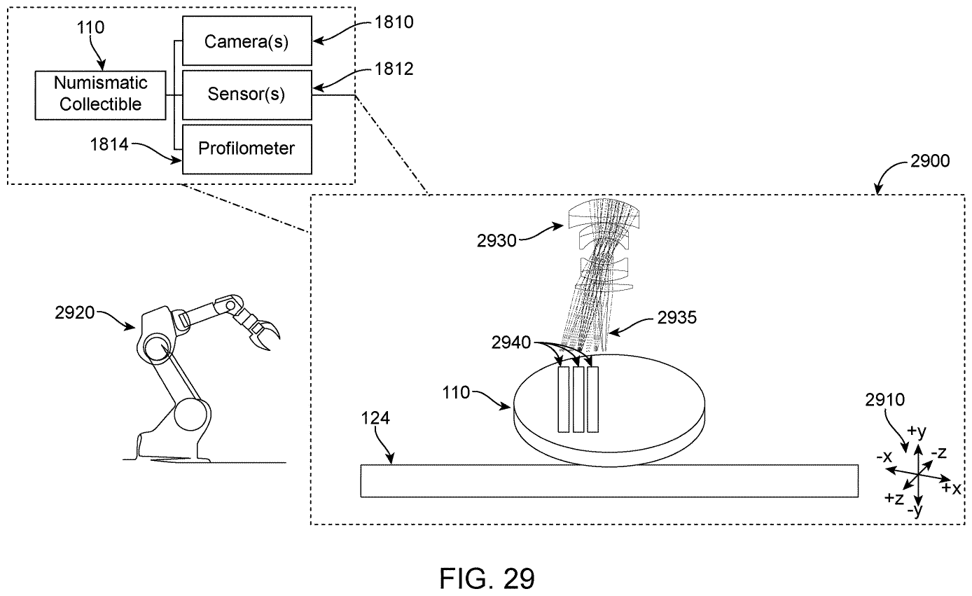

FIG. 29 schematically illustrates moving components that may be part of the computerized system 100, which comprises an image acquisition device 120. In some embodiments, as part of the computerized system (see FIG. 18, reference 1800), at least one component of the image acquisition device 120 is capable of movement. The schematic 2900 illustrates examples of the moving components when using a non-contact profilometer, according to embodiments of the present disclosure. A perspective view of a stage 124 with a numismatic collectible 110 on the surface is shown. In some embodiments, the stage is capable of moving in at least one of X, Y, or Z 2910 to position a coin for data capture by a camera 1810, sensor 1812, or profilometer 1814. In some embodiments, the numismatic collectible 110 may need to be repositioned by the stage 124 more than once for reasons such as analyzing the entirety of the numismatic collectible or moving it between different analysis techniques. In some embodiments, the numismatic collectible 110 is further repositioned by a robotic arm 2920 or a human. In some embodiments, for example when using structured light illumination technology, non-contact profilometry is achieved by optics 2930 that project a pattern 2935 onto the surface structure 2940 of the object. The pattern 2935 is scanned over the surface for the receiver lens to detect changes, such as banding or bending, in response to changes in the topography or topology of the surface. Mathematical analysis, such as triangulation, may then used to calculate and measure the height of the surface.

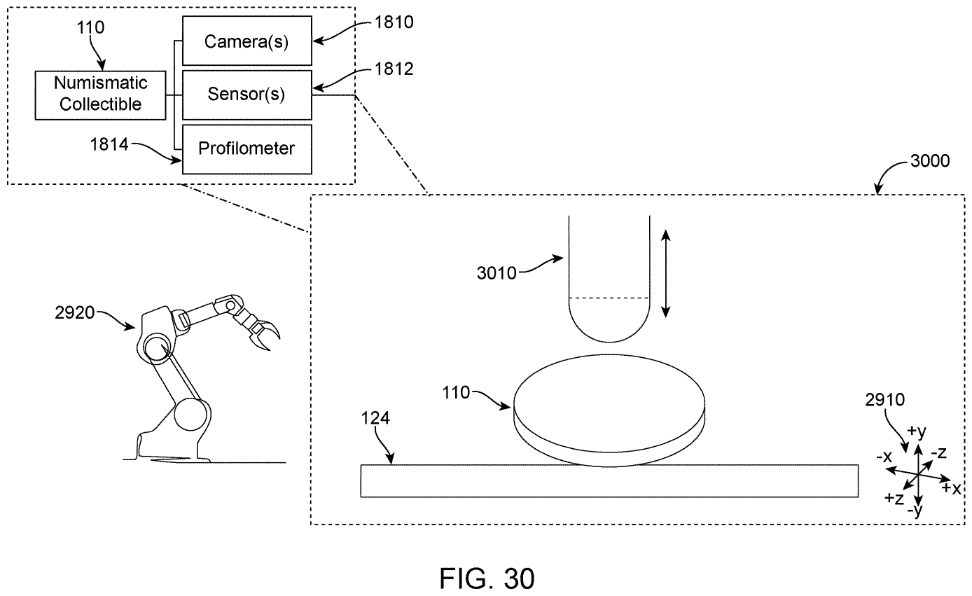

FIG. 30 schematically illustrates moving components that may comprise components of an image acquisition device 120. In some embodiments, as part of the computerized system (see FIG. 18, reference 1800), at least one component of the image acquisition device 120 is capable of movement. The schematic 3000 illustrates examples of the moving components when using a contact profilometer, in accordance with some embodiments. A perspective view of a stage 124 with a numismatic collectible 110 on the surface is shown. In some embodiments, the stage is capable of moving in at least one of X, Y, or Z 2910 to position a coin for data capture by a camera 1810, sensor 1812, or profilometer 1814. In some embodiments, the numismatic collectible 110 may be repositioned by the stage 124 more than once for reasons such as analyzing the entirety of the numismatic collectible or moving it between different analysis techniques. In some embodiments, the numismatic collectible 110 is further repositioned by a robotic arm 2920 or a human. In some embodiments, for example when using an elastomeric sensor technology system, contact profilometry is achieved by moving the profilometer's sensor 3010 across the entire surface of the numismatic collectible 110 such that sufficient resolution is captured of the numismatic collectible 110 as disclosed herein. In some embodiments, movement of the contact surface 3010 (e.g., the elastomer or stylus head) is performed by the contact profilometer or a multi-axis arm supporting it, for example. Other methods of moving the contact surface 3010 known in the art can also be used.

Table 1 details a set of Grading Criteria suitable for incorporation in accordance with the present disclosure, which have been used by the numismatic industry to evaluate the grade and therefore value of a numismatic collectible as described herein. This list provides examples of criteria that can be used to train the AI algorithms as disclosed herein, and there exists a wide range of numismatic collectibles including new issues still being designed and released. A person of ordinary skill in the art can modify the AI algorithms in accordance with the present disclosure. For example, strike designations such as Full Head and Full Bell Lines did not exist before their respective series were minted, in accordance with some embodiments. There also exists a long history of improvements or changes to the grading system including the use of numerical grades (i.e., 1-70) described in the mid-1900's instead of word descriptors (e.g., Fine or About Uncirculated), the more recent expansion of the number of numerical grades (e.g., expanding the list of Mint State grades to 11 grades) in 1986, the assignment of a “Star” designation (e.g., 63*) beginning circa 2001 to denote “exceptional eye appeal”, or the advent of “Plus” grades (e.g., 63+) circa 2010 to denote a high end example for the assigned grade, in accordance with some embodiments. There is also the changing demands of collectors and professionals in the industry, and a person of ordinary skill in the art can modify the system as described herein accordingly. An example of a strike designation that is commonly demanded by collectors but is not officially recognized by any of the top grading services, is the “Full Hand” Strike Designation on Walking Liberty Half Dollar collectibles, which can be incorporated in accordance with embodiments of the present disclosure.

Embodiments of the present disclosure can be utilized to provide additional computerized grading capabilities not readily achievable with manual grading, such as the evaluation of one or more of topography or topology, for example topology data derived from topography data. Using measurements, algorithms, data science, thresholds, statistics-based models, and other techniques, data from Table 1 about the numismatic collectible 110 is collected and applied to the five main categories: Strike, Luster, Wear, Marks, and Eye Appeal. Some of the Grading Criteria in Table 1 are also assessed separately from those five categories (e.g., Strike Designations, Copper Color, and Contrast) as part of determining the grade of a collectible, in accordance with some embodiments of the present disclosure. For example, a Proof Lincoln Cent's grade might be Proof 68 Red Deep Cameo. In some embodiments, the categories should not be considered mutually exclusive; for example, the Eye Appeal of a coin may factor in data from the Luster and Contrast sections of Table 1.

TABLE 1
Grading Criteria

| Category | Criteria |
|---|---|
| Authenticity & | Dimensions (e.g., diameter [mm], thickness |
| Identification | [mm], weight [g]) |
| | Type |
| | Denomination |
| | Year of Manufacture |
| | Place of Manufacture |
| | Method of Manufacture (Proof or Business |
| | strike) |
| | Name of Manufacturer |
| | (artist/sculptor/designer/Mint) |
| | Known Counterfeit Defects |
| | Mint Error Type (steps of deviation from |
| | intended manufacture) |
| | Variety (deviation between Dies) |
| | Chemistry (bulk and/or surface composition) |
| | Hub Type |
| | Die State and/or Die Erosion |
| | Reed Count |
| | Edge Analysis (e.g., lettering, edge style, |
| | alignment) |
| Eye Appeal | Toning |
| | Reflectivity |
| | Cleanliness (e.g., fingerprints and dirt) |
| | Prooflike Qualities (Die state, |
| | Reflectivity/gloss, and Depth) |
| | Exceptional Mirror Finish |
| | Cameo Qualities (Depth and Completeness of |
| | Contrast) |
| | Minting Errors or Defects |
| | Severe or Poorly Located Marks |
| | Light Damage |
| | Overall Surface Preservation |
| Surface | Variations from Golden Image |
| | Marks (Impact Damage) |
| | Scratches (Abrasion) |
| | Wheelmark |
| | Stains |
| | Tape, Lacquer, or Other Residue |
| | Polishing |
| | Smoothing |
| | Alteration |
| Luster | Type |
| | Intensity or Quality |
| | Depth |
| Strike | Variations from golden image |
| | Degree of Detail Completion (aka Die Filling) |
| Strike Designations | Full Bands |
| | Full Head |
| | Full Torch |
| | Full Steps |
| | Full Bell Lines |
| Surface Reflectivity | Non-Prooflike |
| | Prooflike |
| | Deep Mirror Prooflike |
| Contrast | Non-Cameo |
| | Cameo |
| | Ultra Cameo |
| Copper Color | Red |
| | Red Brown |
| | Brown Red |
| | Brown |
| Alterations | Questionable Toning Pattern or Color Scheme |
| | Altered Surface |
| | Altered Date |
| | Mintmark Added, Removed, or Modified |
| No Grade Reasons | PVC |
| | Rims Filed |
| | Counterfeit or Unverifiable Authenticity |
| | Cleaned |
| | Questionable Toning Pattern or Colors |
| | Lamination |
| | Holed or Holed & Plugged |
| | Planchet Flaw or Other Mint Made |
| | Irregularities |
| | Scratch |
| | Environmental Damage |
| | Corrosion |
| | Damage |
| | Graffiti |
| | Rim Dings |
| | Moved Metal |
| | Wheelmark |
| | Stained |
| | Residue |
| | Altered Surface |
| | Repair |
| | Ex-Jewelry |
| | Mechanical Damage |
| | Whizzed |
| | Tooling |
| | Smoothing |
| | Burnishing |
| | Spot or Corrosion Removed |

The data of the collectible 110 can be acquired in any suitable way. In some embodiments, the data comprises topology data, such as surface profilometry data, for example 3D surface profilometry data. The surface profilometry data can be acquired by a contact or a non-contact method, for example. Examples of suitable technologies for obtaining 3D surface profile data in accordance with the present disclosure include optical measurements, structured light illumination, interferometry, white light interferometry, contact sensing, elastomeric sensor technology, and stylus measurements. In some embodiments, the topology data comprises 3D surface profilometry data. In some embodiments, the 3D surface profilometry data is generated with one or more components of a commercially available non-contact surface profiling device, or with a commercially available system, such as structure light illumination systems manufactured by Keyence, for example. Alternatively or in combination, the 3D surface profile data can be acquired with a contact system, such as an elastomeric sensor technology system from GelSight.

In some embodiments, the 3D topology data may comprise 3D surface profile data with a height resolution of better than one or more of 50 micrometers (μm), 10 μm, 5 μm, 1 μm, 0.5 μm and a lateral resolution of better than one or more 50 μm, 25 μm, 10 μm 5 μm, 1 μm, 0.5 μm, for example.

Embodiments of the present disclosure may include one or more of the following list of relevant features:
1) The computerized grading system uses one or more systems to collect data about and/or measurements from a collectible object. That plurality of data can be used alone and/or in conjunction with a human to evaluate the state of preservation and related characteristics (i.e., grade) of the collectible.
2) The key measurement from the collectible object that differentiates us from any prior art is the topological data. This may be collected using contact, non-contact, or some combination.
3) All or part of the data from the collectible object is stored as a digital twin of the object. Assuming the collectible object is not otherwise altered, the data, or mathematical transformations of the data, are a fingerprint of the collectible object.
4) The computerized grading system assesses the identity and authenticity of the collectible.
5) The computerized grading system takes in information about the components of grading a numismatic collectible (e.g., wear, marks, strike, luster, and eye appeal) and processes the information to generate the score report for the components of grading (i.e., strike, marks, luster, wear, and eye appeal) and/or a grade report.
6) Strike quality and strike designations can be evaluated quantitatively with the measured data instead of qualitatively by the human eye.
7) Wear, marks, strike, luster, and eye appeal can each be evaluated quantitatively, or mapped to a quantitative scale (e.g., mapping the measured criteria for eye appeal to a numeric scale) instead of qualitative estimations performed by the human eye of professional graders.
8) Prefixes (e.g., method of manufacture) and Suffixes (e.g., prooflike, cameo contrast, copper color, or strike designations) of the grade(s) assigned in the score report(s) or grade report can be identified and/or evaluated by the computerized grading system.
9) The various forms of damage, alterations, counterfeits, or other no grade reasons are assessed by the computerized grading system. In some embodiments, no grade report is generated because of damage, alterations, counterfeits, and the report may state “No Grade”, along with a reason for not providing the grade, for example.
10) Aspects of the grade report may be broken down into “sub-grades”. For example, strike could receive its own numeric score as a sub-grade.
11) The computerized grading system can operate in single or batch mode. The system can also operate within the confines of an office or as a remote/mobile grading apparatus.
12) The collected data or results of the score report(s) or grade report from the computerized system can be used alone or in combination with human expertise for finalizing the grade report and evaluation of the collectible.
13) The numismatic collectible is placed into a protective slab containing a unique identifier and at least one component of the score report(s) or Grade Report data. At least one method, such as the unique identifier, can be used to look up the collectible, its grade report, and potentially other information about it in a database.

Although reference is made to a numismatic collectible, embodiments of the present disclosure can be used to evaluate any object as described herein.

As described herein, the computing devices and systems described and/or illustrated herein broadly represent any type or form of computing device or system capable of executing computer-readable instructions, such as those contained within the modules described herein. In their most basic configuration, these computing device(s) may each comprise at least one memory device and at least one physical processor.

The term “memory” or “memory device,” as used herein, generally represents any type or form of volatile or non-volatile storage device or medium capable of storing data and/or computer-readable instructions. In one example, a memory device may store, load, and/or maintain one or more of the modules described herein. Examples of memory devices comprise, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In addition, the term “processor” or “physical processor,” as used herein, generally refers to any type or form of hardware-implemented processing unit capable of interpreting and/or executing computer-readable instructions. In one example, a physical processor may access and/or modify one or more modules stored in the above-described memory device. Examples of physical processors comprise, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor. The processor may comprise a distributed processor system, e.g. running parallel processors, or a remote processor such as a server, and combinations thereof.

Although illustrated as separate elements, the method steps described and/or illustrated herein may represent portions of a single application. In addition, in some embodiments one or more of these steps may represent or correspond to one or more software applications or programs that, when executed by a computing device, may cause the computing device to perform one or more tasks, such as the method step.

In addition, one or more of the devices described herein may transform data, physical devices, and/or representations of physical devices from one form to another. Additionally or alternatively, one or more of the modules recited herein may transform a processor, volatile memory, non-volatile memory, and/or any other portion of a physical computing device from one form of computing device to another form of computing device by executing on the computing device, storing data on the computing device, and/or otherwise interacting with the computing device.

The term “computer-readable medium,” as used herein, generally refers to any form of device, carrier, or medium capable of storing or carrying computer-readable instructions. Examples of computer-readable media comprise, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

A person of ordinary skill in the art will recognize that any process or method disclosed herein can be modified in many ways. The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed.

The various exemplary methods described and/or illustrated herein may also omit one or more of the steps described or illustrated herein or comprise additional steps in addition to those disclosed. Further, a step of any method as disclosed herein can be combined with any one or more steps of any other method as disclosed herein.

The processor as described herein can be configured to perform one or more steps of any method disclosed herein. Alternatively or in combination, the processor can be configured to combine one or more steps of one or more methods as disclosed herein.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of” or “one or more of”. Finally, for ease of use, the terms “including” and “having” (and their derivatives), as used in the specification and claims, are interchangeable with and shall have the same meaning as the word “comprising.

The processor as disclosed herein can be configured with instructions to perform any one or more steps of any method as disclosed herein.

It will be understood that although the terms “first,” “second,” “third”, etc. may be used herein to describe various layers, elements, components, regions or sections without referring to any particular order or sequence of events. These terms are merely used to distinguish one layer, element, component, region or section from another layer, element, component, region or section. A first layer, element, component, region or section as described herein could be referred to as a second layer, element, component, region or section without departing from the teachings of the present disclosure.

As used herein, the term “or” is used inclusively to refer items in the alternative and in combination, unless there is a clear indication to the contrary.

As used herein, the terms “or” and “and/or” are used interchangeably.

As used herein, characters such as numerals refer to like elements.

The terms “processor” and “computer” are used interchangeably in the present disclosure.

As used herein, “e.g.” means “for example”.

As used herein the term “um” means “micrometer”.

As used herein, the terms “based on” and “in response to” are used interchangeably.

The present disclosure includes the following numbered clauses.
1. A method of comparing an object with a reference, the method comprising:
receiving data acquired from the object, the data comprising topography data; and
comparing the topography data with reference topography data.
2. The method of clause 1, further comprising generating a digital twin of the object from the topography data and comparing the digital twin with a reference digital twin comprising the reference topography data.
3. The method of any preceding clause, wherein the acquired data comprises reflectance data and the topography data is registered with the reflectance data to generate the digital twin of the object.
4. The method of any preceding clause, wherein the reference digital twin comprises the reference topography data and the reference reflectance data.
5. The method of any preceding clause, wherein the digital twin of the object comprises data of one or more of 3D shape profile data, ID data, strike data, luster data, wear data, eye appeal data, marks data, cameo data, no grade data or toning data.
6. The method any preceding clause, wherein the reference digital twin comprises data of one or more of 3D shape profile data, ID data, strike data, luster data, wear data, eye appeal data, marks data, cameo data, no grade data or toning data.
7. The method of any preceding clause, wherein the data acquired from the object is evaluated with one or more of an ID algorithm, a strike algorithm, a luster algorithm, a wear algorithm, an eye appeal algorithm, a marks algorithm, a cameo algorithm, a no grade algorithm, or a toning algorithm.
8. The method of any preceding clause, further comprising acquiring camera image data and profilometer data from the object, the camera image data comprising an array of intensity values across a two dimensional pixelated array, the profilometer data comprising 3D topography data of a surface of the collectible.
9. The method of any preceding clause, wherein the camera image data is acquired with a first illumination condition and the profilometer data is acquired with a second illumination condition different from the first illumination condition.
10. The method of any preceding clause, wherein the first illumination condition is configured to determine luster from a reflective surface of the collectible.
11. The method of any preceding clause, wherein the object or a source of illumination is moved between the first illumination condition and the second illumination condition.
12. The method any preceding clause, wherein the topography data is aligned with the camera data with one or more of translation or rotation of the camera data or the topography data.
13. The method of any preceding clause, wherein the digital twin data of the object comprises lateral (xy) data with a resolution finer than 25 μm over a lateral distance of at least 1 mm across and elevational data with a resolution finer than 1 μm an elevation of at least 0.01 mm.
14. The method of any preceding clause, wherein the digital twin data of the object comprises lateral (xy) data with a resolution finer than 25 μm over a lateral distance of at least 15 mm across and elevational data with a resolution finer than 1 μm an elevation of at least 0.1 mm.
15. The method of any preceding clause, wherein at least one component of an imaging device is moved to acquire the topography data and optionally wherein the topography data comprises 3D topography data.
16. The method of any preceding clause, wherein the object is identified with a library of 3D shape profiles of a plurality of reference objects and the object is identified in response to a comparison of the 3D shape profile of the object with the 3D shape profiles of objects in the library.
17. The method of any preceding clause, wherein once the object has been identified, the object is compared with reference data of a corresponding object in the library of objects.
18. The method of any preceding clause, wherein trained artificial intelligence (AI) algorithm compares the topography data with reference topography data.
19. The method of any preceding clause, wherein the trained AI algorithm comprises one or more of an identification algorithm, a strike algorithm, a luster algorithm, a wear algorithm, an eye appeal algorithm, a marks algorithm, a visual contrast algorithm, a no grade algorithm, or a toning algorithm.
20. The method of any preceding clause, wherein the trained AI algorithm comprises one or more of the strike algorithm, the wear algorithm, or the marks algorithm.
21. The method of any preceding clause, wherein the AI algorithm comprises one or more of the luster algorithm, or the visual contrast algorithm.
22. A method of grading a collectible, the method comprising:
receiving data acquired from a collectible; and
generating a grade report of the collectible in response to the data.
23. The method of claim 22, wherein the data comprises topology data.
24. The method of any preceding clause, wherein the topology data comprises surface profile data of the collectible.
25. The method of any preceding clause, wherein the topology data has been derived from topography data.
26. The method of any preceding clause, wherein the surface profile data comprises 3D surface profilometry data.
27. The method of any preceding clause, wherein generating the report comprises inputting the data from the collectible into a trained artificial intelligence (AI) algorithm and optionally wherein the data comprises topology data.
28. The method of any preceding clause, wherein the trained AI algorithm comprises one or more of an identification algorithm, a strike algorithm, a luster algorithm, a wear algorithm, an eye appeal algorithm, a marks algorithm, a cameo algorithm, a no grade algorithm, or a toning algorithm.
29. The method of any preceding clause, wherein the data comprises topology or topography data and the AI algorithm comprises one or more of the strike algorithm, the wear algorithm, or the marks algorithm.
30. The method of any preceding clause, wherein the data comprises data from an image of the collectible and the AI algorithm comprises one or more of a luster algorithm, or a cameo algorithm.
31. The method of any preceding clause, further comprising generating an output image, the output image identifying a feature related to the grade report.
32. The method of any preceding clause, wherein a bounding box or keypoints have been overlaid on the output image to identify the feature.
33. The method of any preceding clause, further comprising generating a digital twin of the collectible.
34. The method of any preceding clause, wherein the digital twin of the collectible is compared to golden digital twin to evaluate the collectible.
35. The method of any preceding clause, wherein the digital twin comprises data of one or more of 3D shape profile data, ID data, strike data, luster data, wear data, eye appeal data, marks data, cameo data, no grade data or toning data.
36. The method of any preceding clause, wherein the golden digital twin comprises data of one or more of 3D shape profile data, ID data, strike data, luster data, wear data, eye appeal data, marks data, cameo data, no grade data or toning data.
37. The method of any preceding clause, wherein the data acquired from the collectible is evaluated with one or more of an ID algorithm, a strike algorithm, a luster algorithm, a wear algorithm, an eye appeal algorithm, a marks algorithm, a cameo algorithm, a no grade algorithm, or a toning algorithm.
38. The method of any preceding clause, further comprising acquiring camera image data and profilometer data, the camera image data comprising an array of intensity values across a two dimensional pixelated array, the profilometer data comprising 3D topography data of a surface of the collectible.
39. The method of any preceding clause, wherein the camera image data is acquired with a first illumination condition and the profilometer data is acquired with a second illumination condition different from the first illumination condition.
40. The method of any preceding clause, wherein the collectible or a source of illumination is moved between a first illumination condition and a second illumination condition.
41. The method of any preceding clause, wherein the first illumination condition is configured to determine luster from a reflective surface of the collectible.
42. The method of any preceding clause, wherein the data comprises topography data and camera data.
43. The method of any preceding clause, wherein the topography data is aligned with the camera data with one or more of translation or rotation of the camera data or the topography data.
44. The method of any preceding clause, wherein the digital twin data of the object comprises lateral (xy) data with a resolution finer than 25 μm over a lateral distance of at least 1 mm across and elevational data with a resolution finer than 1 μm an elevation of at least 0.01 mm.
45. The method of any preceding clause, wherein the digital twin data of the object comprises lateral (xy) data with a resolution finer than 25 μm over a lateral distance of at least 15 mm across and elevational data with a resolution finer than 1 μm an elevation of at least 0.1 mm.
46. The method any preceding clause, wherein the collectible is placed on a stage.
47. The method of any preceding clause, wherein the collectible is removed from the stage.
48. The method of any preceding clause, wherein at least one component of an imaging device is moved to acquire the topography data and optionally wherein the topography data comprises 3D topography data.
49. A non-transitory computer readable medium configured with instructions, which when executed by a processor, cause the processor to perform the method of any of the preceding clause and optionally wherein the object comprises a numismatic collectible.
50. An apparatus to grade an object, the apparatus comprising a processor configured to perform the method of any of the preceding clause and optionally wherein the object comprises a numismatic collectible.

Embodiments of the present disclosure have been shown and described as set forth herein and are provided by way of example only. One of ordinary skill in the art will recognize numerous adaptations, changes, variations and substitutions without departing from the scope of the present disclosure. Several alternatives and combinations of the embodiments disclosed herein may be utilized without departing from the scope of the present disclosure and the inventions disclosed herein. Therefore, the scope of the presently disclosed inventions shall be defined solely by the scope of the appended claims and the equivalents thereof.

What is claimed is:

1. A method of comparing an object with a reference, the method comprising:
receiving data acquired from the object, the data comprising topography data; and
comparing the topography data with reference topography data.

2. The method of claim 1, further comprising generating a digital twin of the object from the topography data and comparing the digital twin with a reference digital twin comprising the reference topography data.

3. The method of claim 2, wherein the acquired data comprises reflectance data and the topography data is registered with the reflectance data to generate the digital twin of the object.

4. The method of claim 3, wherein the reference digital twin comprises the reference topography data and the reference reflectance data.

5. The method of claim 2, wherein the digital twin of the object comprises data of one or more of 3D shape profile data, ID data, strike data, luster data, wear data, eye appeal data, marks data, cameo data, no grade data or toning data.

6. The method claim 2, wherein the reference digital twin comprises data of one or more of 3D shape profile data, ID data, strike data, luster data, wear data, eye appeal data, marks data, cameo data, no grade data or toning data.

7. The method of claim 1, wherein the data acquired from the object is evaluated with one or more of an ID algorithm, a strike algorithm, a luster algorithm, a wear algorithm, an eye appeal algorithm, a marks algorithm, a cameo algorithm, a no grade algorithm, or a toning algorithm.

8. The method of claim 1, further comprising acquiring camera image data and profilometer data from the object, the camera image data comprising an array of intensity values across a two dimensional pixelated array, the profilometer data comprising 3D topography data of a surface of the collectible.

9. The method of claim 8, wherein the camera image data is acquired with a first illumination condition and the profilometer data is acquired with a second illumination condition different from the first illumination condition.

10. The method of claim 9, wherein the first illumination condition is configured to determine luster from a reflective surface of the collectible.

11. The method of claim 9, wherein the object or a source of illumination is moved between the first illumination condition and the second illumination condition.

12. The method of claim 1, wherein the topography data is aligned with the camera data with one or more of translation or rotation of the camera data or the topography data.

13. The method of claim 1, wherein the digital twin data of the object comprises lateral (xy) data with a resolution finer than 25 μm over a lateral distance of at least 1 mm across and elevational data with a resolution finer than 1 μm an elevation of at least 0.01 mm.

14. The method of claim 13, wherein the digital twin data of the object comprises lateral (xy) data with a resolution finer than 25 μm over a lateral distance of at least 15 mm across and elevational data with a resolution finer than 1 μm an elevation of at least 0.1 mm.

15. The method of claim 1, wherein at least one component of an imaging device is moved to acquire the topography data and optionally wherein the topography data comprises 3D topography data.

16. The method of claim 1, wherein the object is identified with a library of 3D shape profiles of a plurality of reference objects and the object is identified in response to a comparison of the 3D shape profile of the object with the 3D shape profiles of objects in the library.

17. The method of claim 16, wherein once the object has been identified, the object is compared with reference data of a corresponding object in the library of objects.

18. The method of claim 1, wherein trained artificial intelligence (AI) algorithm compares the topography data with reference topography data.

19. The method of claim 18, wherein the trained AI algorithm comprises one or more of an identification algorithm, a strike algorithm, a luster algorithm, a wear algorithm, an eye appeal algorithm, a marks algorithm, a visual contrast algorithm, a no grade algorithm, or a toning algorithm.

20. The method of claim 19, wherein the trained AI algorithm comprises one or more of the strike algorithm, the wear algorithm, or the marks algorithm.

21. The method of claim 19, wherein the AI algorithm comprises one or more of the luster algorithm, or the visual contrast algorithm.
